(19) United States
(12) Patent Application Publication
(10) Pub. No.: US 2023/0402336 A1
(43) Pub. Date: Dec. 14, 2023

(54) SEMICONDUCTOR MODULE

(71) Applicant: FUJI ELECTRIC CO., LTD., Kanagawa (JP)

(72) Inventor: Hiroyuki NOGAWA, Matsumoto-city (JP)

(21) Appl. No.: 18/453,341

(22) Filed: Aug. 22, 2023

Related U.S. Application Data
(63) Continuation of application No. PCT/JP2022/030235, filed on Aug. 8, 2022.

(30) Foreign Application Priority Data
Sep. 9, 2021 (JP) 2021-147221

(51) Int. Cl. H01L 23/12; H01L 25/18; H01L 25/07; H01L 23/00; H01L 23/538

(52) U.S. Cl. CPC H01L 23/12; H01L 25/18; H01L 25/072; H01L 24/48; H01L 24/49; H01L 23/5386; H01L 2224/48155; H01L 2224/48137; H01L 2224/4903; H01L 2924/1203; H01L 2924/1304

(57) ABSTRACT

Provided is a semiconductor module including: a reverse conducting first switching element which is provided on one of an upper arm and a lower arm; a reverse conducting second switching element which is provided on another of the upper arm and the lower arm; a first path member which is electrically connected to one of a gate electrode and an emitter electrode of the first switching element; and a second path member which is electrically connected to another of the gate electrode and the emitter electrode of the first switching element. The first path member is provided to be closer to the second switching element than the second path member, and current flowing through the first path member flows in antiparallel with a reverse recovery current of an arm provided with the second switching element.

The contents of the following patent application(s) are incorporated herein by reference:
NO. 2021-147221 filed in JP on Sep. 9, 2021, and
NO. PCT/JP2022/030235 filed in WO on Aug. 8, 2022

### BACKGROUND

### 1. Technical Field

The present invention relates to a semiconductor module.

### 2. Related Art

Conventionally, a semiconductor module on which a switching element is mounted is known (for example, see Patent Documents 1 to 3).
Patent Document 1: International Publication No. 2017/199580
Patent Document 2: Japanese Patent Application Publication No. 2011-188540
Patent Document 3: Japanese Patent Application Publication No. 2020-98921

### BRIEF DESCRIPTION OF THE DRAWINGS

FIG. 1A illustrates an outline of a configuration of a semiconductor module 100.

FIG. 1B illustrates an example of an a-a′ cross section of a semiconductor assembly 102.

FIG. 1C is an example of an enlarged view of the semiconductor assembly 102.

FIG. 1D illustrates a relationship between a gate current Ig flowing through a gate wiring member 12 and a reverse recovery current Irr.

FIG. 1E is a main circuit diagram of the semiconductor module 100 according to an example.

FIG. 2A illustrates an example of a configuration of a semiconductor module 500 according to a comparative example.

FIG. 2B illustrates a relationship between an auxiliary emitter current Ie flowing through an auxiliary emitter wiring member 514 and the reverse recovery current Irr.

FIG. 3 illustrates current/voltage characteristics at the time of switching of the semiconductor module 100.

FIG. 4A is a circuit diagram at time T1 in FIG. 3, illustrating an on state of a switching element 10 arranged in an upper arm.

FIG. 4B is a circuit diagram at time T2 in FIG. 3, illustrating an off state of the switching element 10 arranged in the upper arm.

FIG. 4C is a circuit diagram at time T3 in FIG. 3, illustrating the on state of the switching element 10 arranged in the upper arm.

FIG. 5A is a circuit diagram at time T1 in FIG. 3, illustrating the on state of the switching element 10 arranged in a lower arm.

FIG. 5B is a circuit diagram at time T2 in FIG. 3, illustrating the off state of the switching element 10 arranged in the lower arm.

FIG. 5C is a circuit diagram at time T3 in FIG. 3, illustrating the on state of the switching element 10 arranged in the lower arm.

FIG. 6A illustrates switching characteristics of the semiconductor module 500 as the comparative example.

FIG. 6B illustrates switching characteristics of the semiconductor module 100 according to the example.

FIG. 7 illustrates a modification of the configuration of the semiconductor module 100.

FIG. 8A is an enlarged view of a modification of the semiconductor assembly 102.

FIG. 8B is an enlarged view of a modification of the semiconductor assembly 102.

FIG. 8C is an enlarged view of a modification of the semiconductor assembly 102.

FIG. 8D is an enlarged view of a modification of the semiconductor assembly 102.

FIG. 8E is an enlarged view of a modification of the semiconductor assembly 102.

FIG. 8F is an enlarged view of a modification of the semiconductor assembly 102.

FIG. 8G is an enlarged view of a modification of the semiconductor assembly 102.

FIG. 9A is an enlarged view of the modification of the semiconductor assembly 102.

FIG. 9B is an enlarged view of the modification of the semiconductor assembly 102.

FIG. 9C is an enlarged view of the modification of the semiconductor assembly 102.

FIG. 9D is an enlarged view of the modification of the semiconductor assembly 102.

FIG. 9E is an enlarged view of the modification of the semiconductor assembly 102.

FIG. 9F is an enlarged view of the modification of the semiconductor assembly 102.

FIG. 9G is an enlarged view of the modification of the semiconductor assembly 102.

FIG. 9H is an enlarged view of the modification of the semiconductor assembly 102.

FIG. 10A is an enlarged view of the modification of the semiconductor assembly 102.

FIG. 10B is an enlarged view of the modification of the semiconductor assembly 102.

FIG. 10C is an enlarged view of the modification of the semiconductor assembly 102.

FIG. 10D is an enlarged view of the modification of the semiconductor assembly 102.

FIG. 10E is an enlarged view of the modification of the semiconductor assembly 102.

FIG. 10F is an enlarged view of the modification of the semiconductor assembly 102.

FIG. 10G is an enlarged view of the modification of the semiconductor assembly 102.

FIG. 10H is an enlarged view of the modification of the semiconductor assembly 102.

FIG. 11A is an enlarged view of the modification of the semiconductor assembly 102.

FIG. 11B is an enlarged view of the modification of the semiconductor assembly 102.

FIG. 11C is an enlarged view of the modification of the semiconductor assembly 102.

FIG. 11D is an enlarged view of the modification of the semiconductor assembly 102.

FIG. 11E is an enlarged view of the modification of the semiconductor assembly 102.

FIG. 11F is an enlarged view of the modification of the semiconductor assembly 102.

FIG. 11G is an enlarged view of the modification of the semiconductor assembly 102.

FIG. 11H is an enlarged view of the modification of the semiconductor assembly 102.

### DESCRIPTION OF EXEMPLARY EMBODIMENTS

Hereinafter, the present invention will be described through embodiments of the invention, but the following embodiments do not limit the invention according to claims. In addition, not all combinations of features described in the embodiment are essential to the solution of the invention.

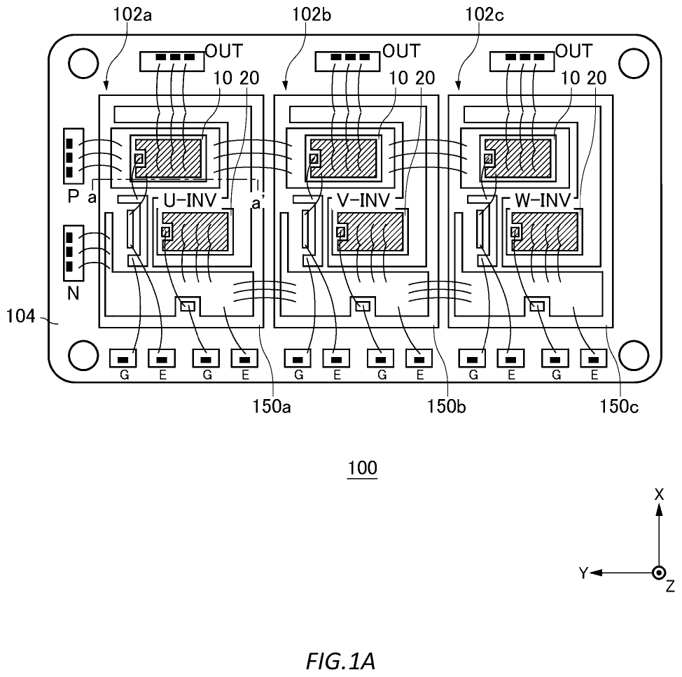

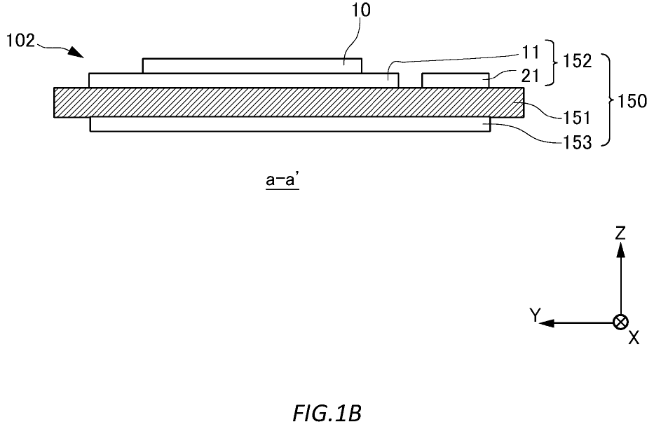

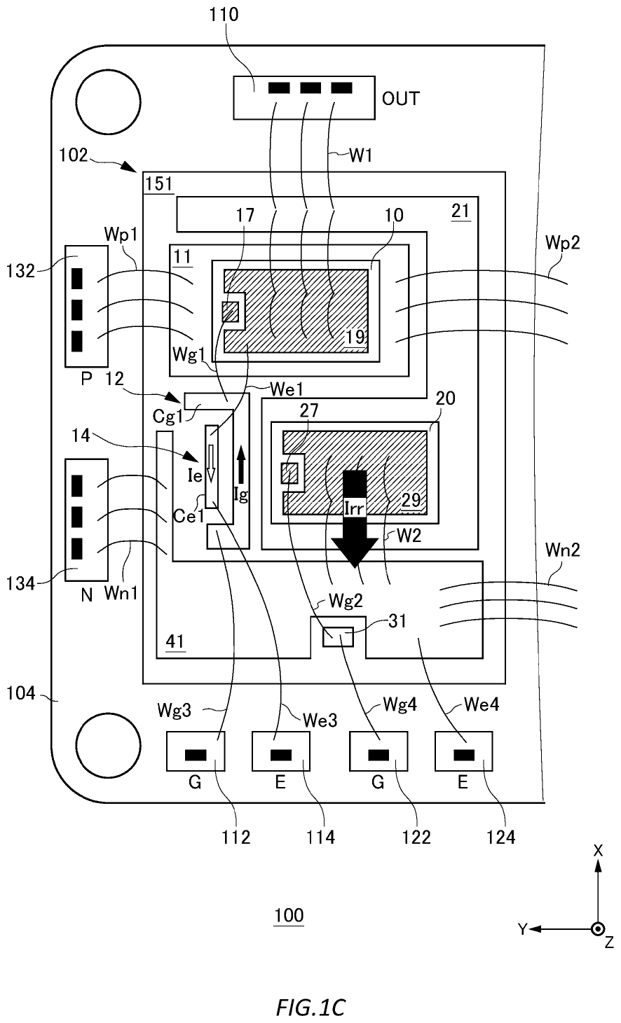

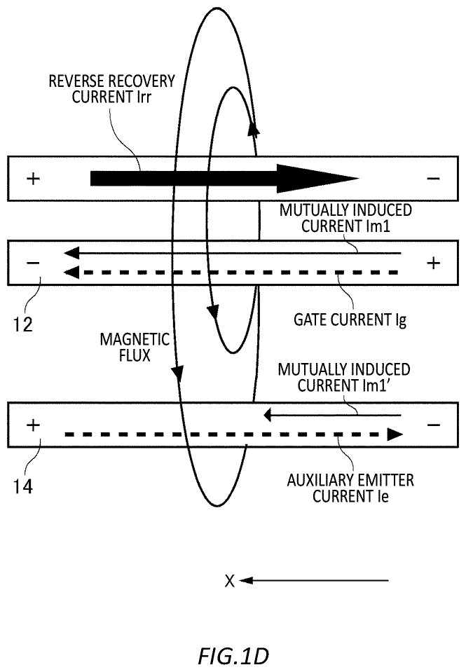

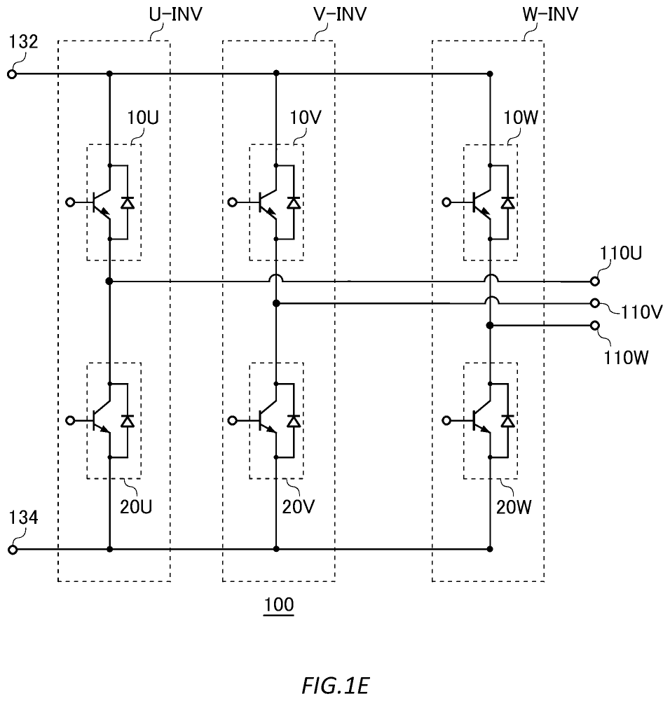

FIG. 1A illustrates an outline of a configuration of a semiconductor module 100. The semiconductor module 100 includes a plurality of semiconductor assemblies 102. The semiconductor module 100 of the present example includes three semiconductor assemblies 102a to 102c, but is not limited thereto.

The semiconductor module 100 may be applied to a power conversion device such as a power module constituting an inverter circuit. For example, when the semiconductor module 100 constitutes a three-phase inverter circuit, the semiconductor assemblies 102a to 102c may correspond to a U phase, a V phase, and a W phase of the three-phase inverter circuit, respectively.

The semiconductor assembly 102 includes a switching element 10, a switching element and a laminated substrate 150. The semiconductor assembly 102 is accommodated in a housing 104 of the semiconductor module 100. The semiconductor assembly 102 may be sealed with an arbitrary sealing resin material in the housing 104.

The switching element 10 and the switching element 20 are reverse conducting switching elements arranged in the laminated substrate 150. The reverse conducting switching element is a switching element constituted by a transistor and a freewheeling diode that allow currents to flow in antiparallel with each other. Each of the switching element 10 and the switching element 20 may be constituted by one chip. For example, each of the switching element 10 and the switching element 20 is a reverse-conducting IGBT (RC-IGBT) including an insulated gate bipolar transistor (IGBT) and a free wheel diode (FWD). The switching element 10 and the switching element 20 may be an element in which a SiC-MOS and a SiC-SBD are integrated, or may be an element in which a body diode of the SiC-MOS is caused to function as a freewheeling diode.

The switching element 10 is a reverse conducting switching element provided on one of an upper arm and a lower arm. The switching element 20 is a reverse conducting switching element provided on the other of the upper arm and the lower arm. In the present example, the switching element 10 is arranged on the upper arm, and the switching element 20 is arranged on the lower arm, but the switching element 10 may be arranged on the lower arm, and the switching element 20 may be arranged on the upper arm.

The switching element 10 and the switching element 20 are mounted on the laminated substrate 150. The laminated substrate 150 may be a Direct Copper Bonding (DCB) substrate or an Active Metal Brazing (AMB) substrate. In the present example, the main surface of the laminated substrate 150 is an XY plane. The semiconductor module 100 of the present example includes three laminated substrates 150a to 150c arranged in a Y-axis direction, but the number and arrangement method of the laminated substrates 150 are not limited thereto.

The semiconductor module 100 includes a plurality of legs each of which is constituted by an upper arm and a lower arm. The plurality of legs are arranged on the laminated substrate 150a, the laminated substrate 150b, and the laminated substrate 150c, respectively. The plurality of legs may be mounted on the laminated substrate 150 in common.

FIG. 1B illustrates an example of an a-a′ cross section of the semiconductor assembly 102. The laminated substrate 150 includes an insulating plate 151, a circuit board 152, and a metal plate 153.

The insulating plate 151 is formed of a flat insulating material having an arbitrary thickness in a Z-axis direction and having an upper surface and a lower surface. The insulating plate 151 may be formed of a ceramic material such as alumina (Al₂O₃), aluminum nitride (AlN), or silicon nitride (Si₃N₄). The insulating plate 151 may be formed of a resin material such as epoxy, an epoxy resin material using a ceramic material as a filler, or the like.

The circuit board 152 is a conductive member having an arbitrary thickness in the Z-axis direction and provided on the upper surface of the insulating plate 151. The metal plate 153 is a conductive member having an arbitrary thickness in the Z-axis direction and provided on the lower surface of the insulating plate 151. The circuit board 152 and the metal plate 153 may be formed of a plate containing a metal material such as copper and a copper alloy. The circuit board 152 and the metal plate 153 may be fixed to the insulating plate 151 by soldering, brazing, or the like. The metal plate 153 may be formed of a thermally conductive material such as copper or aluminum and function as a heat sink.

A first circuit board 11 and a second circuit board 21 are examples of the circuit board 152 provided on the upper surface of the insulating plate 151. The first circuit board 11 and the second circuit board 21 will be described later.

FIG. 1C is an example of an enlarged view of the semiconductor assembly 102. The semiconductor module 100 may include a plurality of semiconductor assemblies 102 having the same configuration as in the present example.

The gate wiring member 12 is electrically connected to a gate electrode 17 of the switching element 10. A gate current Ig flowing from a gate external terminal 112 toward the switching element 10 flows through the gate wiring member 12. The gate wiring member 12 may be constituted by a combination of the circuit board 152 and a wire member.

The gate wiring member 12 of the present example includes a gate control wire Wg1, a gate circuit board Cg1, and a gate control wire Wg3. The gate control wire Wg1 is a wire member for connecting the gate electrode 17 and the gate circuit board Cg1. The gate circuit board Cg1 is an example of the circuit board 152 for causing the gate current Ig to flow to the switching element 10. The gate circuit board Cg1 of the present example has a substantially U shape, but is not limited thereto. The gate control wire Wg3 is a wire member for connecting the gate external terminal 112 and the gate circuit board Cg1.

An auxiliary emitter wiring member 14 is electrically connected to an emitter electrode 19 of the switching element 10. An auxiliary emitter current Ie flowing from the switching element 10 toward an auxiliary emitter external terminal 114 flows through the auxiliary emitter wiring member 14. The auxiliary emitter current Ie is current that returns from the switching element 10 to a control terminal in response to the flow of the gate current Ig from the control terminal to the switching element 10. The auxiliary emitter wiring member 14 may be constituted by a combination of the circuit board 152 and a wire member.

The auxiliary emitter wiring member 14 of the present example includes an auxiliary emitter control wire We1, an auxiliary emitter circuit board Ce1, and an auxiliary emitter control wire We3. The auxiliary emitter control wire We1 is a wire member for connecting the emitter electrode 19 and the auxiliary emitter circuit board Ce1. The auxiliary emitter circuit board Ce1 is an example of the circuit board 152 for causing the emitter current Ie from the switching element 10 to flow. The auxiliary emitter circuit board Ce1 of the present example has an I shape extending in an X-axis direction. The auxiliary emitter control wire We3 is a wire member for connecting the auxiliary emitter external terminal 114 and the auxiliary emitter circuit board Ce1.

Herein, the gate wiring member 12 is either one of a first path member and a second path member. The auxiliary emitter wiring member 14 is the other of the first path member and the second path member. The first path member is a member electrically connected to one of the gate electrode 17 and the emitter electrode 19 of the switching element 10. The second path member is a member electrically connected to the other of the gate electrode 17 and the emitter electrode 19 of the switching element 10. The first path member is provided to be closer to the switching element 20 than the second path member. The current flowing through the first path member flows in antiparallel with a reverse recovery current Irr of the arm provided with the switching element 20. Note that the current flowing in antiparallel may mean not only a case where the currents flow in completely opposite directions, but also a relationship in which a mutually induced current Im1 is generated to strengthen the current flowing through the first path member as described later. The first path member and the second path member may be constituted by a combination of the circuit board 152 and a wire member. Which member of the gate wiring member 12 and the auxiliary emitter wiring member 14 functions as the first path member or the second path member can be changed according to the arrangement of each member in the semiconductor module 100.

The reverse recovery current Irr is current flowing through the switching element 20 at the time of turn-on of the switching element 10 of the opposing arm. A direction in which the reverse recovery current Irr flows is decided according to the arrangement of the switching element 20 and the like. The reverse recovery current Irr in the present example flows to a negative side in the X-axis direction.

The gate wiring member 12 of the present example is arranged such that current flows in antiparallel with the reverse recovery current Irr of the arm provided with the switching element 20. The gate wiring member 12 is provided to be closer to the switching element 20 than the auxiliary emitter wiring member 14. That is, the gate wiring member 12 of the present example functions as the first path member. The gate wiring member 12 of the present example is provided between the auxiliary emitter wiring member 14 and the switching element 20 on the insulating plate 151. More specifically, the gate circuit board Cg1 is provided between the auxiliary emitter circuit board Ce1 and the switching element 20 in a top view. However, the gate wiring member 12 may be provided to be farther from the switching element 20 than the auxiliary emitter wiring member 14 according to the direction of the reverse recovery current Irr. The gate wiring member 12 and the auxiliary emitter wiring member 14 of the present example have the circuit board 152.

The first circuit board 11 is the circuit board 152 on which the switching element 10 is mounted. The first circuit board 11 is electrically connected to the back electrode of the switching element 10 by using a conductive fixing member such as solder. The first circuit board 11 may be electrically connected to a positive electrode terminal 132. The second circuit board 21 is the circuit board 152 on which the switching element 20 is mounted. The second circuit board 21 is electrically connected to the back electrode of the switching element 20 by using a conductive fixing member such as solder.

An output terminal 110 is an external terminal for electrical connection with a load provided outside the semiconductor module 100. The output terminal 110 is provided on one predetermined side of the semiconductor module 100. The output terminal 110 of the present example is provided on a side extending in the Y-axis direction on the positive side of the semiconductor module 100 in the X-axis direction. The position of the output terminal 110 is not limited thereto.

The gate external terminal 112, the auxiliary emitter external terminal 114, the gate external terminal 122, and the auxiliary emitter external terminal 124 are examples of control terminals for controlling the operation of the semiconductor module 100. The control terminal of the present example is provided on a side opposite to the side on which the output terminal 110 is provided. The control terminal of the present example is provided on a side extending in the Y-axis direction on the negative side of the semiconductor module 100 in the X-axis direction.

The gate external terminal 112 is electrically connected to the gate electrode 17 of the switching element 10 via the gate wiring member 12. The gate external terminal 112 of the present example is electrically connected to the gate electrode 17 via the gate control wire Wg1, the gate circuit board Cg1, and the gate control wire Wg3.

The auxiliary emitter external terminal 114 is electrically connected to the emitter electrode 19 of the switching element 10 via the auxiliary emitter wiring member 14. The auxiliary emitter external terminal 114 of the present example is electrically connected to the emitter electrode 19 via the auxiliary emitter control wire We1, the auxiliary emitter circuit board Ce1, and the auxiliary emitter control wire We3.

The gate external terminal 122 is electrically connected to the gate electrode 27 of the switching element 20. The gate external terminal 122 of the present example is electrically connected to the gate electrode 27 via the gate control wire Wg2, a third circuit board 31, and a gate control wire Wg4.

The auxiliary emitter external terminal 124 is electrically connected to the emitter electrode 29 of the switching element 20. The auxiliary emitter external terminal 124 of the present example is electrically connected to the emitter electrode 29 via a main current wire W2, a fourth circuit board 41, and an auxiliary emitter control wire We4.

The gate external terminal 112 of the present example is provided to be farther from the switching element 20 than the auxiliary emitter external terminal 114. That is, the gate external terminal 112 is provided on the positive side in the Y-axis direction with respect to the auxiliary emitter external terminal 114. However, the method of arranging each terminal of the control terminals is not limited to the present example. The control terminals of the present example are arranged in the order of the gate external terminal 112, the auxiliary emitter external terminal 114, the gate external terminal 122, and the auxiliary emitter external terminal 124 toward the negative side in the Y-axis direction. That is, the gate and the emitter of the control terminal of the present example are arranged in the order of GEGE (where G is the gate and E is the emitter).

The third circuit board 31 is electrically connected to the gate electrode 27 of the switching element 20 by the gate control wire Wg2. The third circuit board 31 is electrically connected to the gate external terminal 122 by the gate control wire Wg4.

The fourth circuit board 41 is electrically connected to the emitter electrode 29 of the switching element 20 by the main current wire W2. The fourth circuit board 41 is electrically connected to the auxiliary emitter external terminal 124 by the auxiliary emitter control wire We4. In addition, the fourth circuit board 41 may be electrically connected to a negative electrode terminal 134.

The positive electrode terminal 132 and the negative electrode terminal 134 are provided on one predetermined side of the semiconductor module 100. The positive electrode terminal 132 and the negative electrode terminal 134 of the present example are provided on a side orthogonal to the side on which the output terminal 110 is provided. The positive electrode terminal 132 and the negative electrode terminal 134 may be provided on a side orthogonal to the side on which the control terminal such as the gate external terminal 112 is provided. The positive electrode terminal 132 of the present example is a side extending in the X-axis direction on the positive side of the semiconductor module 100 in the Y-axis direction. The positive electrode terminal 132 of the present example is electrically connected to the first circuit board 11 by a positive electrode side wire Wp1. The negative electrode terminal 134 is electrically connected to the fourth circuit board 41 by a negative electrode side wire Wn1.

The positive electrode side wire Wp2 electrically connects the upper arms of the adjacent legs to each other. For example, the positive electrode side wire Wp2 is bonded to any circuit board of the adjacent semiconductor assembly 102 so as to be electrically connected to the back electrode of the switching element 10 of the adjacent leg. The negative electrode side wire Wn2 electrically connects the lower arms of the adjacent legs to each other. For example, the negative electrode side wire Wn2 is bonded to any circuit board of the adjacent semiconductor assembly 102 so as to be electrically connected to the upper surface electrode of the switching element 20 of the adjacent leg. However, the method of connecting adjacent legs is not limited to the present example.

FIG. 1D illustrates a relationship between the gate current Ig flowing through the gate wiring member 12 and the reverse recovery current Irr. In the present example, the reverse recovery current Irr flows toward the negative side in the X-axis direction, and the gate current Ig flows toward the positive side in the X-axis direction. That is, the gate wiring member 12 is arranged such that the reverse recovery current Irr and the gate current Ig flow in antiparallel.

At the start of the switching, the reverse recovery current Irr increases in the direction of an arrow. As a result, the mutually induced current Im1 generated in the gate wiring member 12 that has received the magnetic flux of the reverse recovery current Irr is induced in a direction of preventing the increase in the reverse recovery current Irr as indicated by an arrow. When the gate current Ig or the auxiliary emitter current Ie flows in the same direction as the mutually induced current Im1, the switching speed at the time of turn-on is increased. When the gate current Ig or the auxiliary emitter current Ie flows in the opposite direction to the mutually induced current Im1, the switching speed at the time of turn-on is reduced.

For example, when the reverse recovery current Irr flows toward the negative side in the X-axis direction, the mutually induced current Im1 flowing toward the positive side in the X-axis direction is generated in the gate wiring member 12 arranged in the vicinity of the reverse recovery current Irr. Accordingly, the gate current Ig is strengthened by the mutually induced current Im1 flowing in the same direction.

In addition, when the reverse recovery current Irr flows toward the negative side in the X-axis direction, a mutually induced current Im1′ flowing toward the positive side in the X-axis direction is generated also in the auxiliary emitter wiring member 14 arranged to be farther from the reverse recovery current Irr than the gate wiring member 12. However, the mutually induced current Im1′ generated in the auxiliary emitter wiring member 14 is smaller than the mutually induced current Im1 generated in the gate wiring member 12 since the mutually induced current Im1′ has a longer distance to the reverse recovery current Irr than the mutually induced current Im1. For this reason, although the mutually induced current Im1′ is generated in a direction of weakening the auxiliary emitter current Ie, an influence on the auxiliary emitter current Ie is smaller than an influence of the mutually induced current Im1 on the gate current Ig. Therefore, when the gate current Ig flows in antiparallel with the reverse recovery current Irr in the gate wiring member 12 provided close to the switching element 20, a switching speed at the time of turn-on increases as a whole.

In the present example, a case where the gate current Ig flowing through the gate wiring member 12 is strengthened has been described, but when the auxiliary emitter wiring member 14 is closer to the switching element 20 than the gate wiring member 12, the auxiliary emitter current Ie flowing through the auxiliary emitter wiring member 14 can be strengthened.

The semiconductor module 100 includes the gate wiring member 12 and the auxiliary emitter wiring member 14 wired so as to avoid that the reverse recovery current Irr inhibits the flow of the gate current Ig or the auxiliary emitter current Ie. Accordingly, the semiconductor module 100 can suppress a decrease in the switching speed at the time of turn-on and reduce a loss.

In particular, when each of the switching element 10 and the switching element 20 is constituted by one chip, the degree of freedom in chip arrangement is lower than that when the transistor and the freewheeling diode are constituted by separate chips, and the transistor and the freewheeling diode of the opposing arm are likely to spatially approach each other. In the semiconductor module 100 of the present example, even when the switching element 10 and the switching element 20 are constituted by one chip as described above, the degree of freedom in chip arrangement can be improved. For example, in the semiconductor module 100 of the present example, even when the control terminal is arranged on the side opposite to the output terminal 110, it is possible to suppress the decrease in the switching speed due to the reverse recovery current Irr by devising the wiring of the gate wiring member 12 and the auxiliary emitter wiring member 14.

The path member of the arm strengthened by the mutually induced current Im1 of the reverse recovery current Irr may be longer than the path member of the other arm. For example, when the gate current Ig of the gate wiring member 12 electrically connected to the switching element 10 is strengthened, the gate wiring member 12 may be longer than the gate wiring member connected to the gate electrode 27 of the switching element 20. Similarly, when the auxiliary emitter current Ie of the auxiliary emitter wiring member 14 electrically connected to the switching element 10 is strengthened, the auxiliary emitter wiring member 14 may be longer than the auxiliary emitter wiring member connected to the emitter electrode 29 of the switching element 20. As described above, by strengthening the current of the arm with the longer path member, the switching speed of the switching element provided in the opposing arm can be made uniform.

FIG. 1E is a main circuit diagram of the semiconductor module 100 according to the example. For example, the semiconductor module 100 functions as a part of an in-vehicle unit that drives a motor of a vehicle. The semiconductor module 100 has the positive electrode terminal 132, the negative electrode terminal 134, an output terminal 110U, an output terminal 110V, and an output terminal 110W.

A leg U-INV includes a set of switching elements 10U and 20U. A leg V-INV includes a set of switching elements 10V and 20V. A leg W-INV includes a set of switching elements 10W and 20W.

The switching element 10U, the switching element 10V, and the switching element 10W constitute the upper arm of the semiconductor module 100. The switching element 20U, the switching element 20V, and the switching element 20W constitute the lower arm of the semiconductor module 100.

Each of the back electrodes of the switching element 10U, the switching element 10V, and the switching element 10W is electrically connected to the positive electrode terminal 132. The front electrodes of the switching element 10U, the switching element 10V, and the switching element 10W are electrically connected to the output terminal 110U, the output terminal 110V, or the output terminal 110W, respectively. Note that in the present example, a case where the switching element is an RC-IGBT has been described, but which of the front electrode and the back electrode is connected can change depending on the direction of the current.

Each of the front electrodes of the switching element 20U, the switching element 20V, and the switching element 20W is electrically connected to the negative electrode terminal 134. The back electrodes of the switching element 20U, the switching element 20V, and the switching element 20W are electrically connected to the output terminal 110U, the output terminal 110V, or the output terminal 110W, respectively. Each switching element may be alternately switched by a signal input to the control terminal of the semiconductor module 100 to function as a three-phase AC inverter circuit.

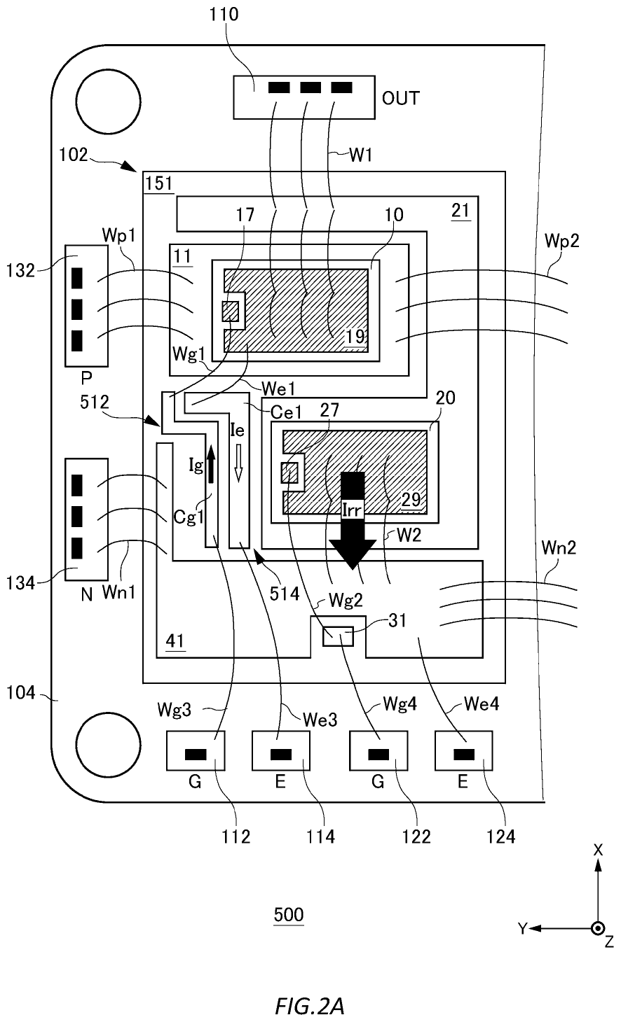

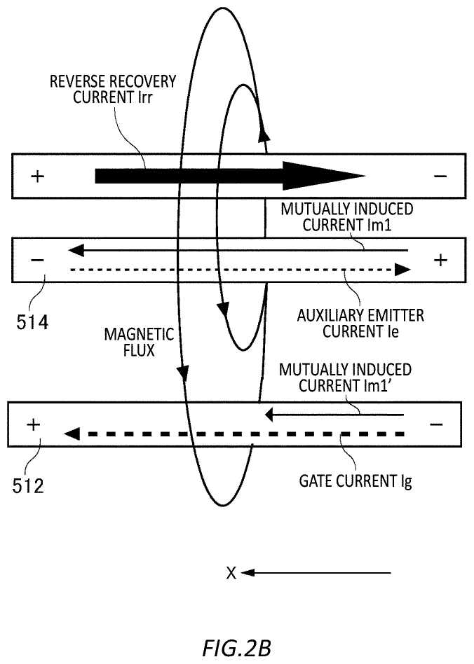

FIG. 2A illustrates an example of a configuration of a semiconductor module 500 according to a comparative example. The semiconductor module 500 of the present example includes an auxiliary emitter wiring member 514 closer to the switching element 20 than the gate wiring member 512. In the auxiliary emitter wiring member 514, the auxiliary emitter current Ie flows in the same direction as the reverse recovery current Irr, and thus is weakened by the influence of the reverse recovery current Irr.

FIG. 2B illustrates a relationship between the auxiliary emitter current Ie flowing through the auxiliary emitter wiring member 514 and the reverse recovery current Irr. In the present example, both the reverse recovery current Irr and the auxiliary emitter current Ie flow toward the negative side in the X-axis direction. When the reverse recovery current Irr flows toward the negative side in the X-axis direction, the mutually induced current Im1 flowing toward the positive side in the X-axis direction is generated in the auxiliary emitter wiring member 514 arranged in the vicinity of the reverse recovery current Irr. Accordingly, the auxiliary emitter current Ie is weakened by the mutually induced current Im1 flowing in a reverse direction. In addition, the mutually induced current Im1′ flowing toward the positive side in the X-axis direction is also generated in the gate wiring member 512. Accordingly, the gate current Ig is strengthened by the mutually induced current Im1 flowing in the reverse direction. However, since the influence of the weakening of the auxiliary emitter current Ie is larger than the influence of the strengthening of the gate current Ig, the overall influence acts to reduce the switching speed at the time of turn-on. Note that in the present example, a case where the auxiliary emitter current Ie flowing through the auxiliary emitter wiring member 514 is weakened has been described, but the gate current Ig flowing through the gate wiring member 512 can also be weakened by the similar arrangement.

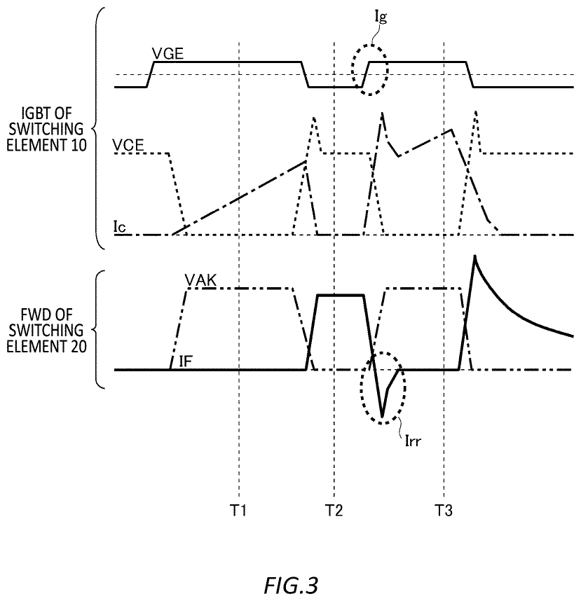

FIG. 3 illustrates current/voltage characteristics at the time of switching of the semiconductor module 100. This drawing illustrates a gate voltage VGE, a collector-emitter voltage VCE, and a collector current Ic of the IGBT of the switching element 10. In addition, this drawing illustrates an anode-cathode voltage VAK and a forward current IF of the FWD of the switching element 20.

Circuit states corresponding to time T1 to time T3 will be described later. Between time T2 and time T3, when the gate current Ig is supplied to the switching element 10 and the IGBT is turned on, the reverse recovery current Irr flows through the opposing arm of the switching element 10. Note that in the present example, a case where the switching element 10 and the switching element 20 are RC-IGBTs has been described, but the type of the switching element is not limited thereto.

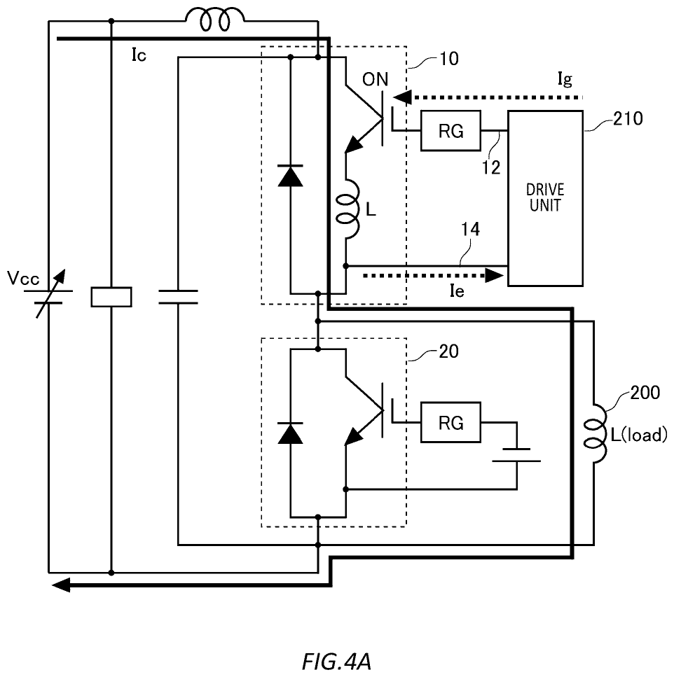

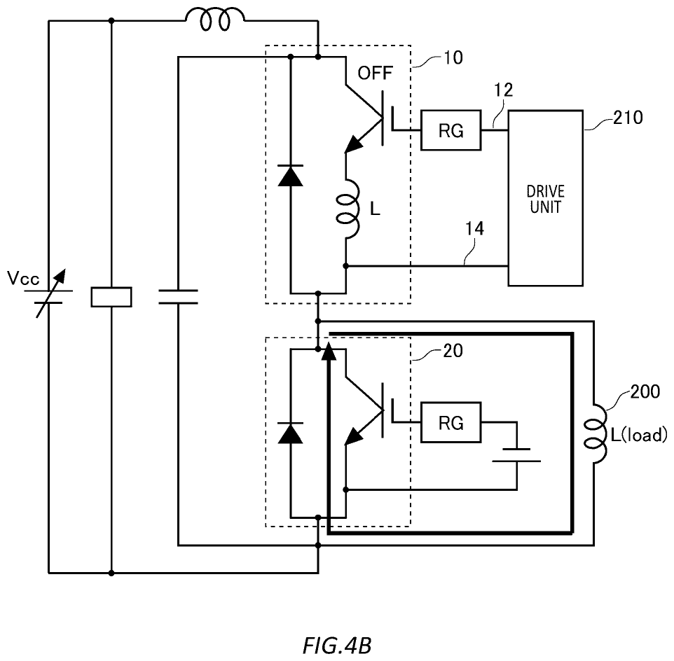

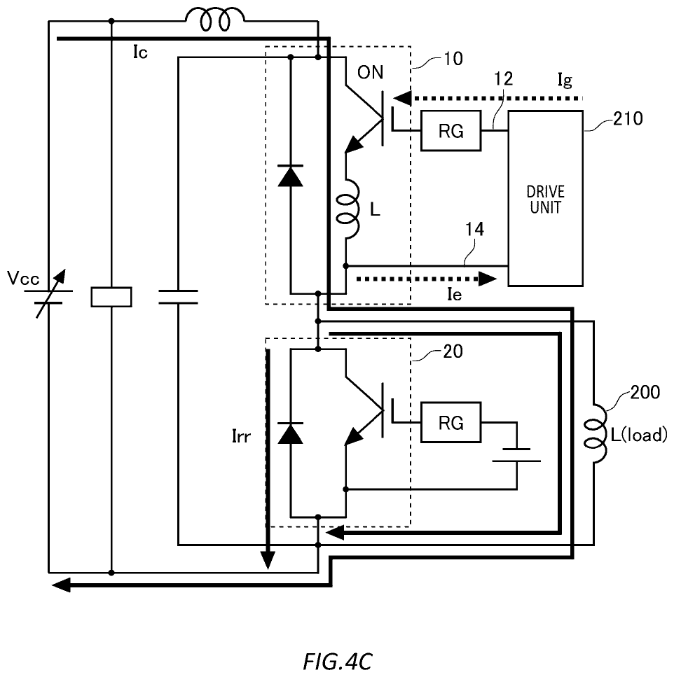

FIG. 4A is a circuit diagram at time T1 in FIG. 3, illustrating an on state of the switching element 10 arranged in the upper arm. The switching element 10 and the switching element 20 in the present example are RC-IGBTs including an IGBT and an FWD. When the IGBT of the switching element 10 is turned on by a drive unit 210, the collector current Ic flows via an inductance L to a load 200 at a constant di/dt. Here, since the relationship of V=Ldlc/dt is established, dlc/dt=V/L is constant.

FIG. 4B is a circuit diagram at time T2 in FIG. 3, illustrating an off state of the switching element 10 arranged in the upper arm. When the IGBT of the switching element 10 is turned off, current flows in a direction in which the inductance L prevents a current change. Then, a loop current flows via the FWD of the switching element 20 arranged in the lower arm. Note that when the switching element 10 arranged in the upper arm is in an off state, the switching element 20 arranged in the lower arm is turned on except for a dead time period, but no current flows through the IGBT of the switching element 20 due to the influence of inductance.

FIG. 4C is a circuit diagram at time T3 in FIG. 3, illustrating the on state of the switching element 10 arranged in the upper arm. The drive unit 210 in the present example supplies the gate current Ig to the switching element 10 arranged in the upper arm. Accordingly, the IGBT of the switching element 10 is turned on, and a current obtained by adding the loop current to the collector current Ic from the switching element 10 flows to the load 200. Then, the reverse recovery current Irr is generated in the FWD of the switching element 20 arranged in the lower arm.

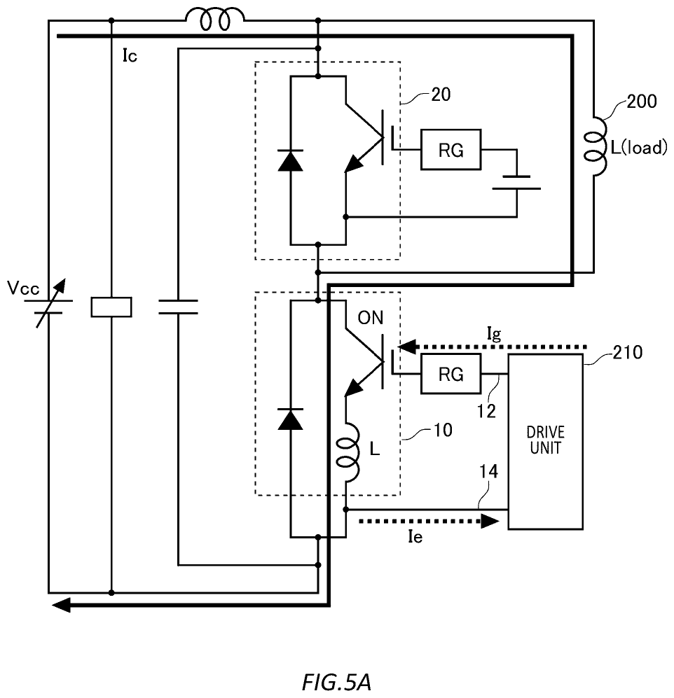

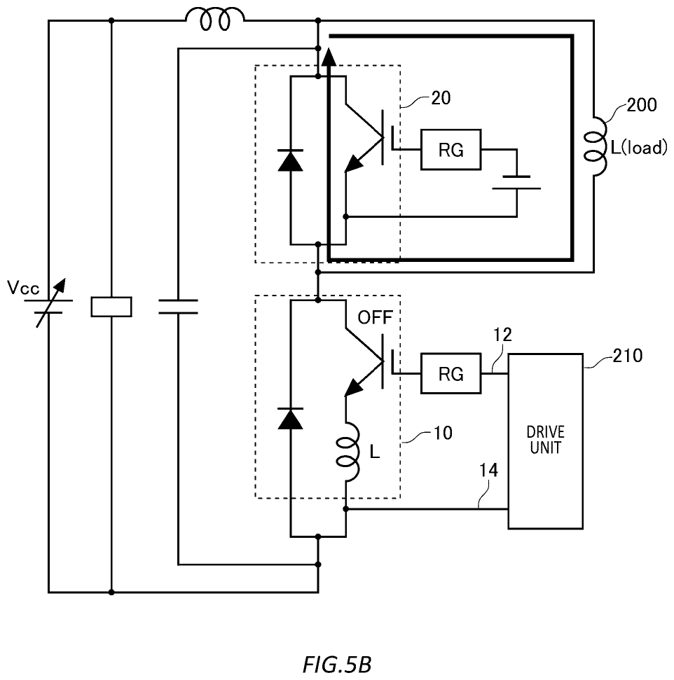

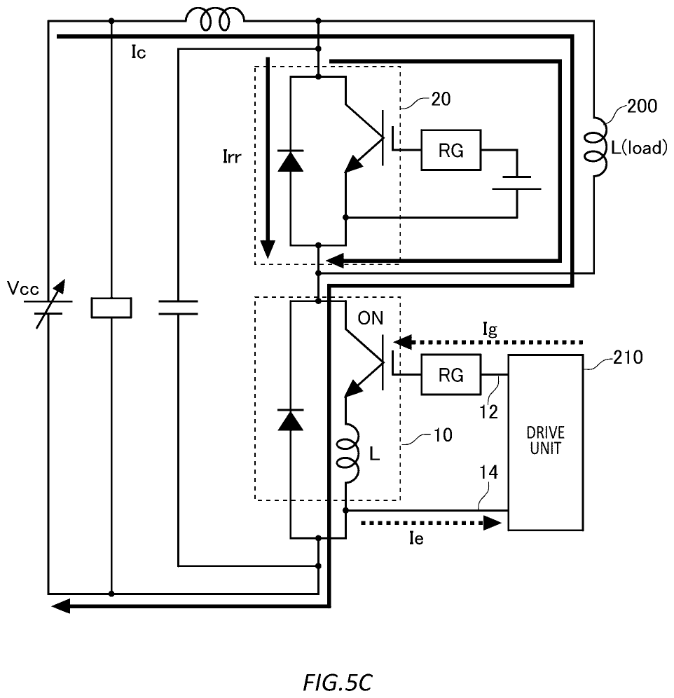

FIG. 5A is a circuit diagram at time T1 in FIG. 3, illustrating the on state of the switching element 10 arranged in the lower arm. That is, FIGS. 4A and 5A are different in whether the upper arm is made conductive or the lower arm is made conductive. Similarly to the case of FIG. 4A, when the IGBT of the switching element 10 is turned on by the drive unit 210, the collector current Ic flows via the inductance L to the load 200 at the constant di/dt. Here, since the relationship of V=Ldlc/dt is established, dlc/dt=V/L is constant.

FIG. 5B is a circuit diagram at time T2 in FIG. 3, illustrating the off state of the switching element 10 arranged in the lower arm. When the IGBT of the switching element 10 is turned off, current flows in a direction in which the inductance L prevents a current change. Then, a loop current flows via the FWD of the switching element 20 arranged in the upper arm. Note that when the switching element 10 arranged in the lower arm is in the off-state, the switching element 20 arranged in the upper arm is turned on except for the dead time period, but no current flows through the IGBT of the switching element 20 due to the influence of inductance.

FIG. 5C is a circuit diagram at time T3 in FIG. 3, illustrating the on state of the switching element 10 arranged in the lower arm. The drive unit 210 in the present example supplies the gate current Ig to the switching element 10 arranged in the lower arm. Accordingly, the IGBT of the switching element 10 is turned on, and a current obtained by adding the loop current to the collector current Ic from the switching element 10 flows to the load 200. Then, the reverse recovery current Irr is generated in the FWD of the switching element 20 arranged in the upper arm.

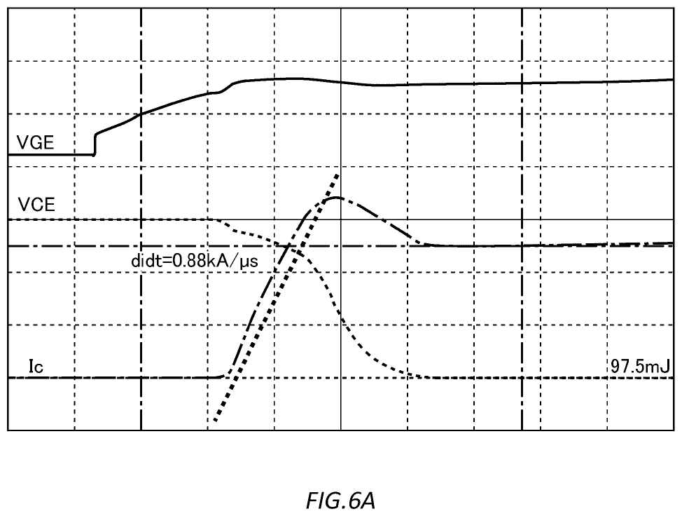

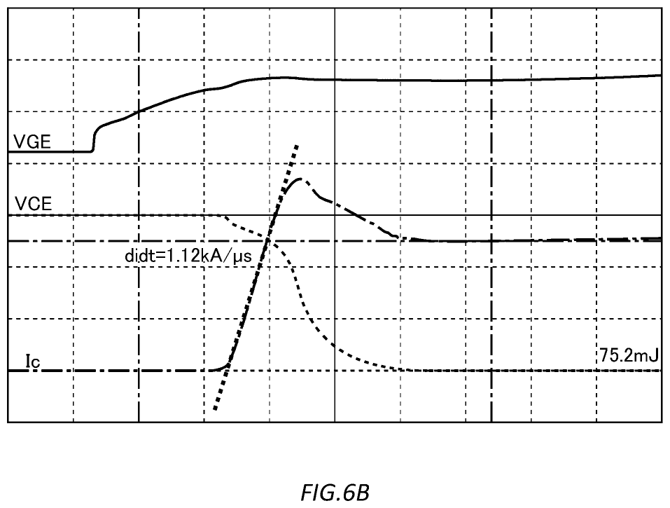

FIG. 6A illustrates switching characteristics of the semiconductor module 500 as the comparative example. This drawing illustrates the gate voltage VGE, the collector-emitter voltage VCE, and the collector current Ic of the IGBT included in the switching element 10 of the semiconductor module 500. In addition, this drawing illustrates the turn-on waveform and the magnitude of the loss of the semiconductor module 500. di/dt (the change rate of the collector current Ic per unit time) at the time of turn-on of the semiconductor module 500 is 0.88 kA/μs. The loss of the semiconductor module 500 is 97.5 mJ.

FIG. 6B illustrates switching characteristics of the semiconductor module 100 according to the example. This drawing illustrates the gate voltage VGE, the collector-emitter voltage VCE, and the collector current Ic of the IGBT included in the switching element 10 of the semiconductor module 100. In addition, this drawing illustrates the turn-on waveform and the magnitude of the loss of the semiconductor module 100. di/dt at the time of turn-on of the semiconductor module 100 is 1.12 kA/μs. The loss of the semiconductor module 100 is 75.2 mJ.

As described above, it can be seen that the switching speed of the semiconductor module 100 is higher than that of the semiconductor module 500, and the loss is improved by approximately 25%. That is, the semiconductor module 100 can suppress the influence of the reverse recovery current Irr on the switching speed and obtain the turn-on characteristic superior to that of the semiconductor module 500.

Next, a modification of the semiconductor module 100 will be described. Also in the modification of the semiconductor module 100, among the gate current Ig and the auxiliary emitter current Ie, the current path of the current antiparallel to the direction of the reverse recovery current Irr is arranged to be closer to the reverse recovery current Irr, and the current path of the current forward to the direction of the reverse recovery current Irr is arranged to be farther from the reverse recovery current Irr. That is, as described with reference to FIG. 1D, the gate current Ig and the auxiliary emitter current Ie are increased as a whole by the influence of the mutually induced current Im1 generated according to the reverse recovery current Irr, so that the switching speed at the time of turn-on is improved.

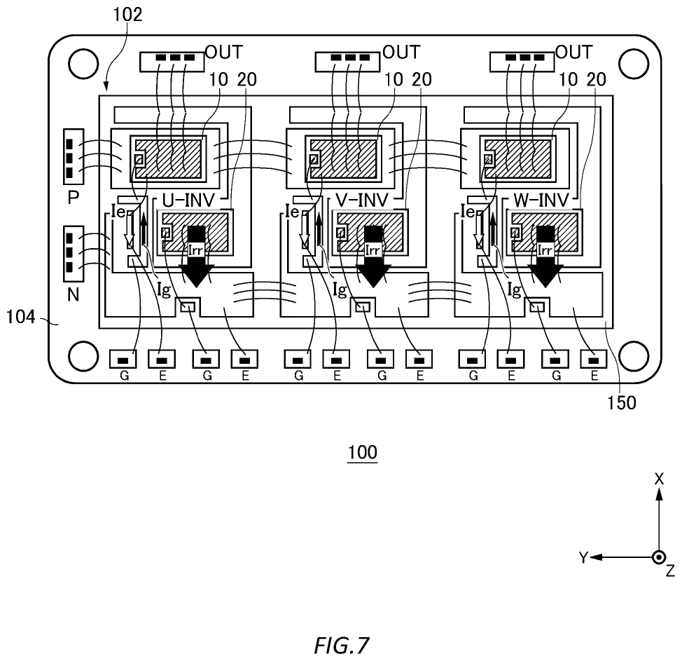

FIG. 7 illustrates a modification of the configuration of the semiconductor module 100. The present example is different from the example of FIG. 1A in that a plurality of legs are mounted on the laminated substrate 150 in common. In the semiconductor module 100 of the present example, configurations corresponding to the U phase, the V phase, and the W phase of the three-phase inverter circuit are mounted on the laminated substrate 150 in common. Other configurations may be the same as those of the semiconductor module 100 in FIG. 1A. As in the present example, even when the plurality of legs are mounted on the laminated substrate 150 in common, the gate wiring member 12 and the auxiliary emitter wiring member 14 are arranged so as to avoid that the reverse recovery current Irr inhibits the flow of the gate current Ig or the auxiliary emitter current Ie.

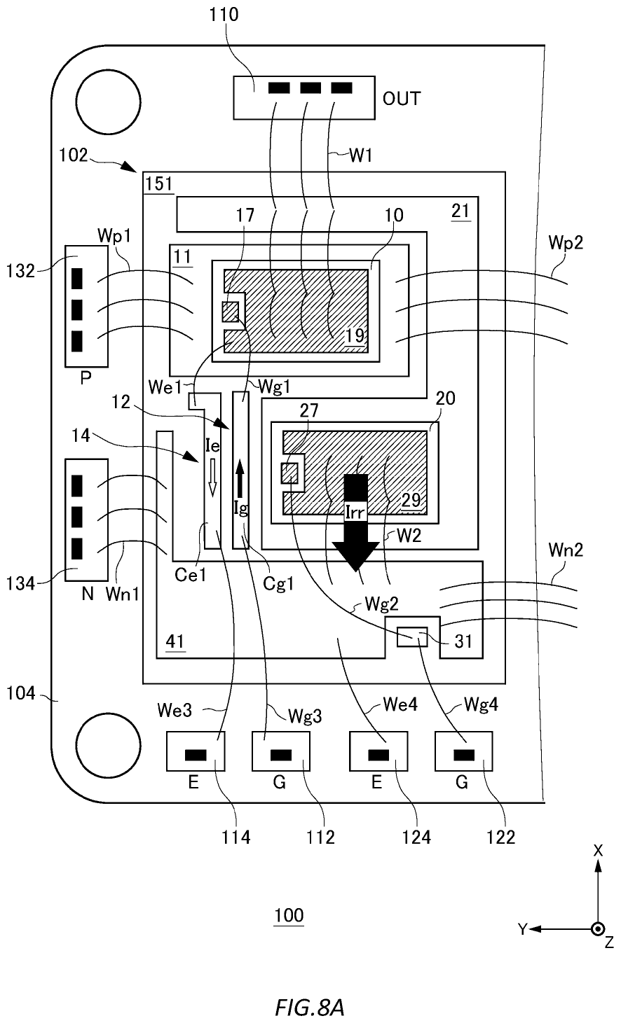

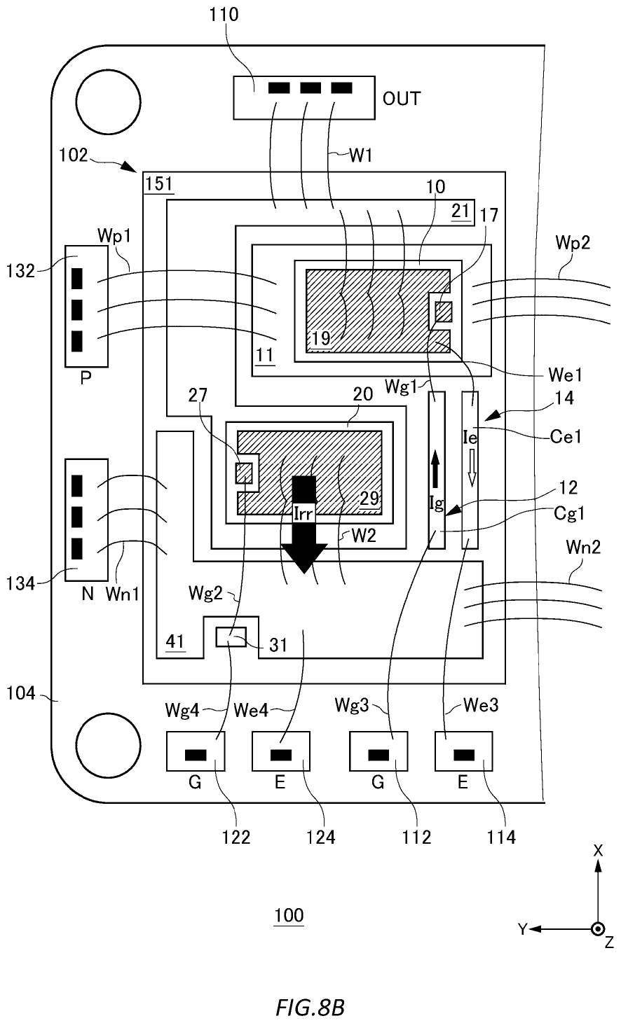

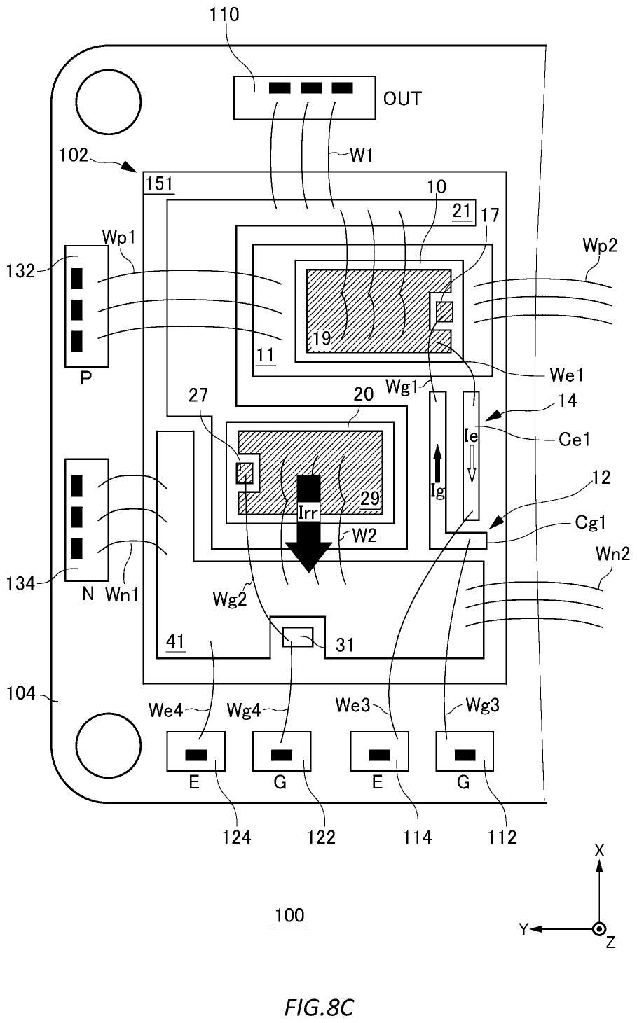

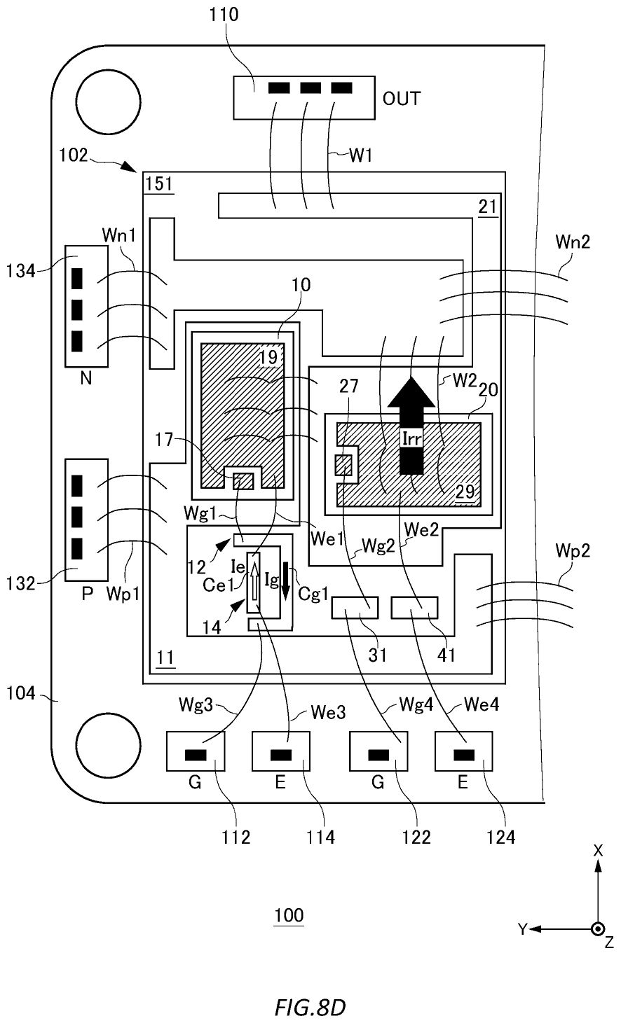

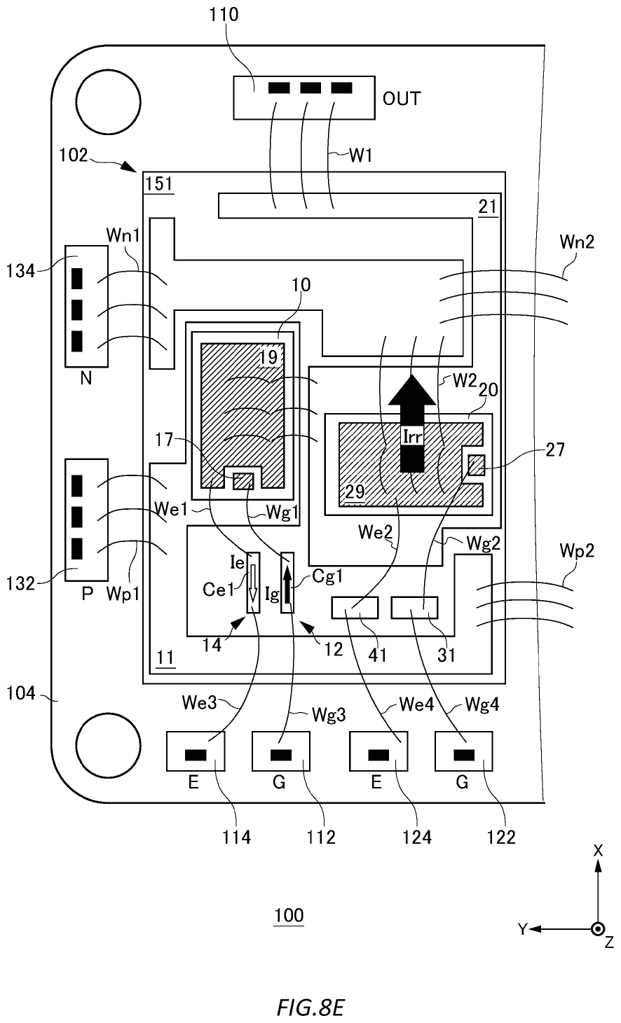

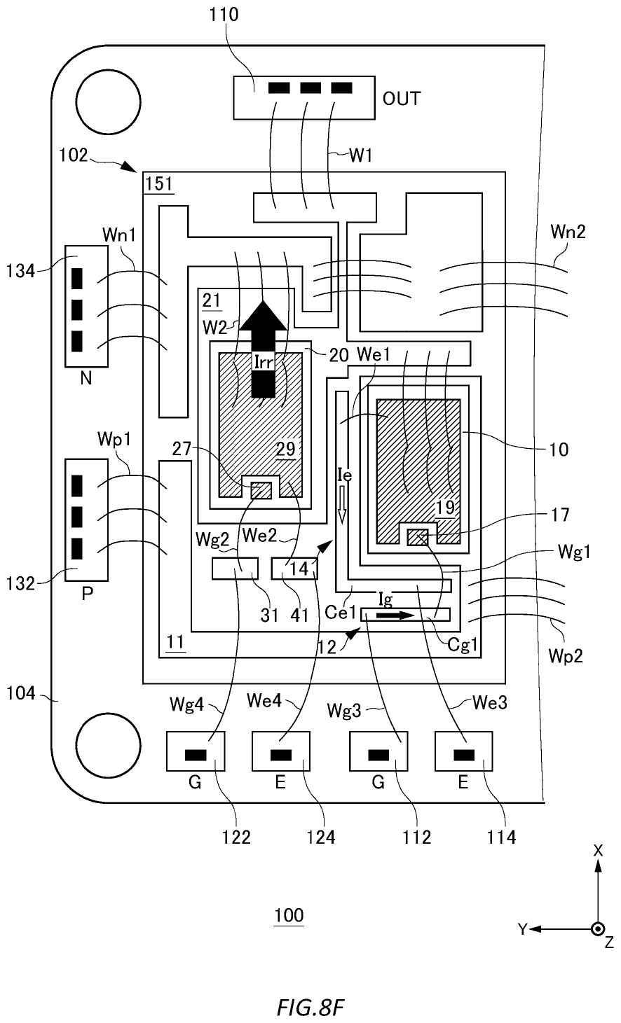

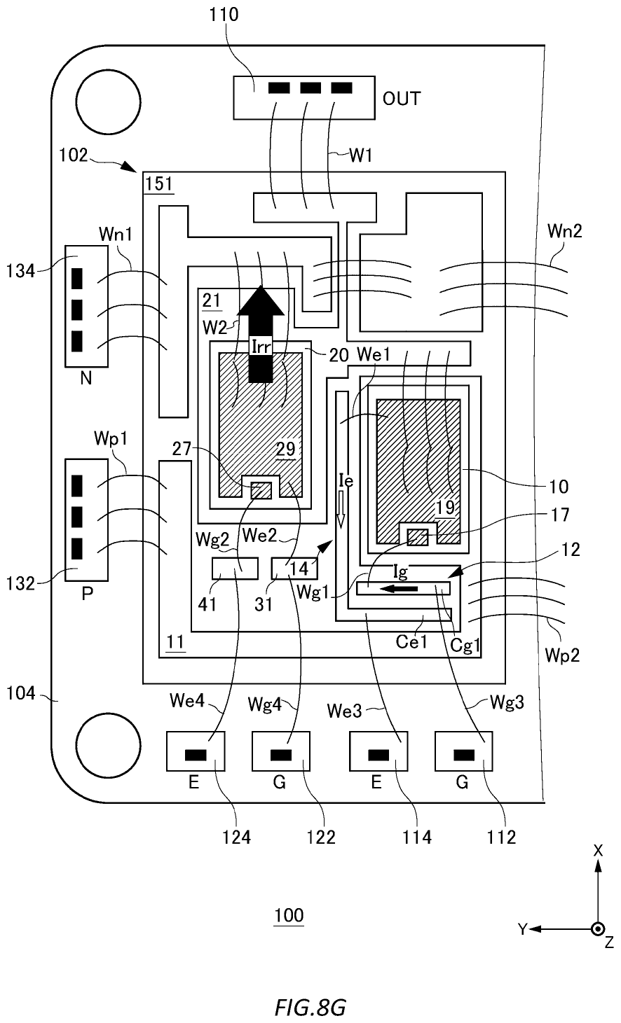

FIG. 8A is an enlarged view of a modification of the semiconductor assembly 102. The present example is different from the example of FIG. 1C in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 1C will be particularly described. The gate external terminal 112 of the present example is provided to be closer to the switching element 20 than the auxiliary emitter external terminal 114.

The gate circuit board Cg1 extends between the switching element 20 and the auxiliary emitter circuit board Ce1 in the X-axis direction. The auxiliary emitter circuit board Ce1 is arranged on the positive side in the Y-axis direction with respect to the gate circuit board Cg1. The auxiliary emitter circuit board Ce1 of the present example has an L shape, but is not limited thereto. Another circuit board 152 such as the fourth circuit board 41 may be provided on the positive side of the auxiliary emitter circuit board Ce1 in the Y-axis direction.

The gate wiring member 12 of the present example is provided to be closer to the switching element 20 than the auxiliary emitter wiring member 14. That is, the gate circuit board Cg1 is provided between the auxiliary emitter circuit board Ce1 and the switching element 20 in the XY plane. The gate wiring member 12 and the auxiliary emitter wiring member 14 of the present example are arranged in the order corresponding to the gate external terminal 112 and the auxiliary emitter external terminal 114 in the Y-axis direction, and are wired without crossing each other in the top view. The gate wiring member 12 through which the gate current Ig antiparallel to the reverse recovery current Irr flows is closer to the switching element 20 than the auxiliary emitter wiring member 14 through which the auxiliary emitter current Ie forward to the direction of the reverse recovery current Irr flows, and a current path is wired so that the gate current Ig and the auxiliary emitter current Ie increase as a whole. The increase in the gate current Ig and the auxiliary emitter current Ie as a whole may refer to that the influence of the increase in these currents due to the reverse recovery current Irr is greater than the influence of the decrease, and may refer to that the switching speed at the time of turn-on is improved.

FIG. 8B is an enlarged view of a modification of the semiconductor assembly 102. The present example is different from the example of FIG. 1C in that the positions of the control terminal connected to the upper arm and the control terminal connected to the lower arm are exchanged. That is, the control terminals of the present example are arranged in the order of the gate external terminal 122, the auxiliary emitter external terminal 124, the gate external terminal 112, and the auxiliary emitter external terminal 114 toward the negative side in the Y-axis direction. In the present example, points different from the example of FIG. 1C will be particularly described. The gate external terminal 112 of the present example is provided to be closer to the switching element 20 than the auxiliary emitter external terminal 114.

The gate wiring member 12 is provided on the negative side in the Y-axis direction with respect to the switching element 20. The gate wiring member 12 includes the gate control wire Wg1, the gate circuit board Cg1, and the gate control wire Wg3. The gate wiring member 12 is provided between the switching element 20 and the auxiliary emitter wiring member 14. The gate circuit board Cg1 extends between the switching element 20 and the auxiliary emitter circuit board Ce1 in the X-axis direction.

The auxiliary emitter wiring member 14 is provided on the negative side in the Y-axis direction with respect to the switching element 20. The auxiliary emitter wiring member 14 includes the auxiliary emitter control wire Wet, the auxiliary emitter circuit board Ce1, and the auxiliary emitter control wire We3. The auxiliary emitter circuit board Ce1 is arranged on the negative side in the Y-axis direction with respect to the gate circuit board Cg1 and extends in the X-axis direction.

As described above, even when the position of the switching element 20 is changed, the gate current Ig flowing through the gate wiring member 12 functioning as the first path member and the reverse recovery current Irr can flow in antiparallel. Note that when the gate wiring member 12 and the auxiliary emitter wiring member 14 are arranged at positions closer to the adjacent semiconductor assembly 102 than the switching element 20, the current path may be wired so that the gate current Ig and the auxiliary emitter current Ie increase as a whole in consideration of the influence of the adjacent semiconductor assembly 102 in addition to the reverse recovery current Irr of the semiconductor assembly 102.

FIG. 8C is an enlarged view of a modification of the semiconductor assembly 102. The present example is different from the example of FIG. 8B in that the control terminals are arranged in the order of EGEG. That is, the control terminals are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 8B will be particularly described. The gate external terminal 112 of the present example is provided to be farther from the switching element 20 than the auxiliary emitter external terminal 114.

The gate circuit board Cg1 is provided between the switching element 20 and the auxiliary emitter circuit board Ce1. The gate circuit board Cg1 of the present example has an L shape, but is not limited thereto. The auxiliary emitter circuit board Ce1 extends in the X-axis direction on the negative side in the Y-axis direction with respect to the gate circuit board Cg1. Another circuit board 152 such as the fourth circuit board 41 may be provided on the positive side of the switching element 20 in the Y-axis direction. Accordingly, even in the relationship with the adjacent semiconductor assembly 102, the gate wiring member 12 and the auxiliary emitter wiring member 14 are arranged so as to avoid that the reverse recovery current Irr inhibits the flow of the gate current Ig or the auxiliary emitter current Ie.

The gate wiring member 12 of the present example is provided to be closer to the switching element 20 than the auxiliary emitter wiring member 14. The gate circuit board Cg1 of the present example is provided between the auxiliary emitter circuit board Ce1 and the switching element 20 in the XY plane. The gate wiring member 12 and the auxiliary emitter wiring member 14 of the present example may be wired to cross each other in the top view. In the present example, the gate circuit board Cg1 and the auxiliary emitter control wire We3 are wired to cross each other.

FIG. 8D is an enlarged view of a modification of the semiconductor assembly 102. The present example is different from the example of FIG. 1C in that the positions of the positive electrode terminal 132 and the negative electrode terminal 134 are exchanged. The positive electrode terminal 132 of the present example is arranged on the negative side in the X-axis direction with respect to the negative electrode terminal 134. In the present example, points different from the example of FIG. 1C will be particularly described.

The gate circuit board Cg1 is provided between the switching element 20 and the auxiliary emitter circuit board Ce1. The gate circuit board Cg1 of the present example has a substantially U shape, but is not limited thereto. The auxiliary emitter circuit board Ce1 extends in the X-axis direction on the positive side in the Y-axis direction with respect to the gate circuit board Cg1. Another circuit board 152 such as the first circuit board 11 may be provided on the positive side of the auxiliary emitter circuit board Ce1 in the Y-axis direction.

The negative electrode terminal 134 of the present example is arranged on the positive side in the X-axis direction with respect to the positive electrode terminal 132, and when the switching element 10 arranged in the upper arm is energized, the reverse recovery current Irr directed to the positive side in the X-axis direction is generated in the lower arm. On the other hand, the gate current Ig directed to the negative side in the X-axis direction flows through the gate circuit board Cg1. Therefore, the gate current Ig close to the switching element 20 flows in antiparallel with the reverse recovery current Irr, and the current path is wired such that the gate current Ig and the auxiliary emitter current Ie increase as a whole.

FIG. 8E is an enlarged view of a modification of the semiconductor assembly 102. The present example is different from the example of FIG. 8D in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 8D will be particularly described. The gate external terminal 112 of the present example is provided to be closer to the switching element 20 than the auxiliary emitter external terminal 114.

The gate circuit board Cg1 extends between the switching element 20 and the auxiliary emitter circuit board Ce1 in the X-axis direction. The auxiliary emitter circuit board Ce1 extends in the X-axis direction on the positive side in the Y-axis direction with respect to the gate circuit board Cg1. Another circuit board 152 such as the first circuit board 11 may be provided on the positive side of the auxiliary emitter circuit board Ce1 in the Y-axis direction. The gate wiring member 12 and the auxiliary emitter wiring member 14 of the present example are arranged in the order corresponding to the gate external terminal 112 and the auxiliary emitter external terminal 114 in the Y-axis direction, and are wired without crossing each other in the top view.

The negative electrode terminal 134 of the present example is arranged on the positive side in the X-axis direction with respect to the positive electrode terminal 132, and when the switching element 10 arranged in the upper arm is energized, the reverse recovery current Irr directed to the positive side in the X-axis direction is generated in the lower arm. On the other hand, the auxiliary emitter current Ie directed to the negative side in the X-axis direction flows through the auxiliary emitter circuit board Ce1. Therefore, the auxiliary emitter current Ie close to the switching element 20 flows in antiparallel with the reverse recovery current Irr, and the current path is wired such that the gate current Ig and the auxiliary emitter current Ie increase as a whole.

FIG. 8F is an enlarged view of a modification of the semiconductor assembly 102. The present example is different from the example of FIG. 8D in that the gate external terminal 112 and the auxiliary emitter external terminal 114 are arranged on the negative side in the Y-axis direction with respect to the gate external terminal 122 and the auxiliary emitter external terminal 124. The control terminals of the present example are arranged in the order of the gate external terminal 122, the auxiliary emitter external terminal 124, the gate external terminal 112, and the auxiliary emitter external terminal 114 toward the negative side in the Y-axis direction. In the present example, points different from the example of FIG. 8D will be particularly described.

The gate circuit board Cg1 extends in the Y-axis direction on the negative side in the X-axis direction with respect to the switching element 10. The gate current Ig flows to the negative side in the Y-axis direction in the gate circuit board Cg1. The auxiliary emitter wiring member 14 is provided to be closer to the switching element 20 than the gate wiring member 12. That is, in the present example, the gate wiring member 12 functions as the second path member, and the auxiliary emitter wiring member 14 functions as the first path member. The auxiliary emitter circuit board Ce1 is arranged on the positive side in the X-axis direction with respect to the gate circuit board Cg1. The auxiliary emitter circuit board Ce1 of the present example has an L shape, but is not limited thereto.

When the switching element 10 arranged in the upper arm is energized, the reverse recovery current Irr directed to the positive side in the X-axis direction is generated in the lower arm. On the other hand, in the auxiliary emitter circuit board Ce1, the auxiliary emitter current Ie directed to the negative side in the X-axis direction flows in the region close to the switching element 20. As described above, even when the arrangement of the control terminal and the switching element 20 is changed, the auxiliary emitter current Ie close to the switching element 20 flows in antiparallel with the reverse recovery current Irr, and the current path is wired such that the gate current Ig and the auxiliary emitter current Ie increase as a whole.

The auxiliary emitter circuit board Ce1 is arranged such that a region, in which the auxiliary emitter current Ie flows in antiparallel with the reverse recovery current Irr, in the L shape is closer to the switching element 20 than a region in which the auxiliary emitter current Ie flows in a direction orthogonal to the reverse recovery current Irr. Accordingly, the current path can be wired more flexibly while improving the switching speed at the time of turn-on.

FIG. 8G is an enlarged view of a modification of the semiconductor assembly 102. The present example is different from the example of FIG. 8F in that the control terminals are arranged in the order of EGEG. That is, the control terminals are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 8F will be particularly described.

The gate circuit board Cg1 extends between the switching element 10 and the auxiliary emitter circuit board Ce1 in the Y-axis direction. The auxiliary emitter circuit board Ce1 is provided between the switching element 20 and the gate circuit board Cg1. The auxiliary emitter circuit board Ce1 of the present example has an L shape, but is not limited thereto. Another circuit board 152 such as the first circuit board 11 may be provided on the positive side of the switching element 20 in the Y-axis direction. Accordingly, even in the relationship with the adjacent semiconductor assembly 102, the gate wiring member 12 and the auxiliary emitter wiring member 14 are arranged so as to avoid that the reverse recovery current Irr inhibits the flow of the gate current Ig or the auxiliary emitter current Ie.

The gate wiring member 12 and the auxiliary emitter wiring member 14 of the present example may be wired to cross each other in the top view. Since the auxiliary emitter circuit board Ce1 has the L shape, the gate wiring member 12 and the auxiliary emitter wiring member 14 easily cross each other. In the present example, the auxiliary emitter circuit board Ce1 and the gate control wire Wg3 are wired to cross each other. In addition, similarly to the example of FIG. 8F, by devising the arrangement of the auxiliary emitter circuit board Ce1 having the L shape, it is possible to more flexibly wire the current path while improving the switching speed at the time of turn-on.

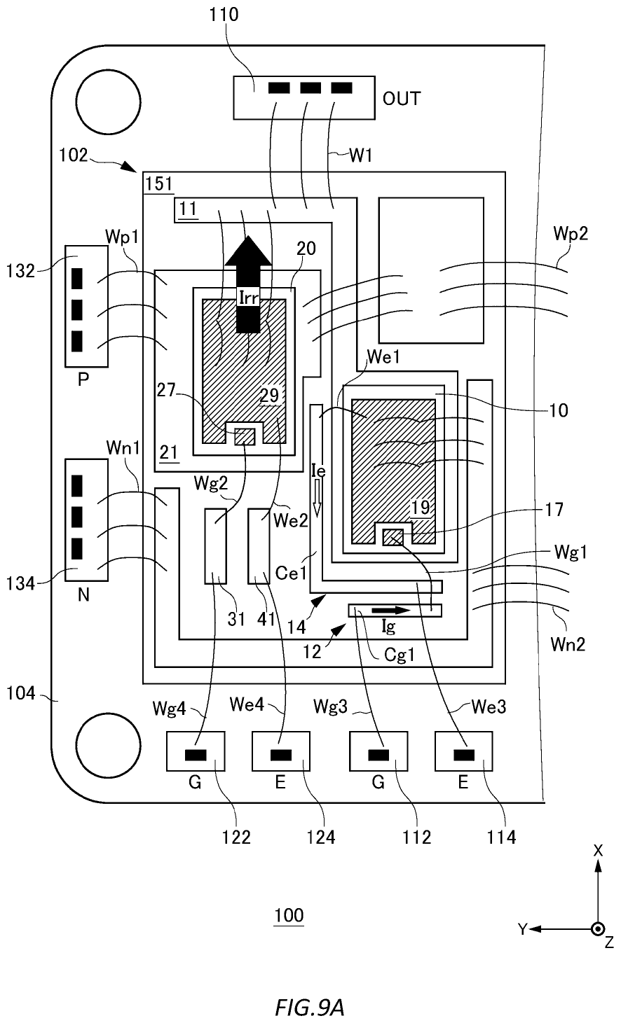

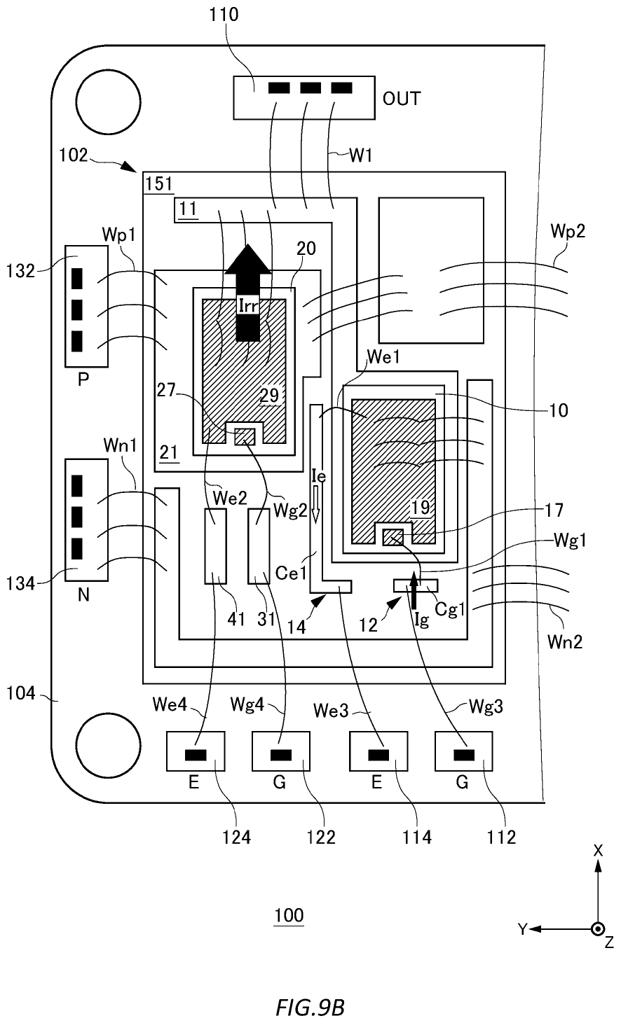

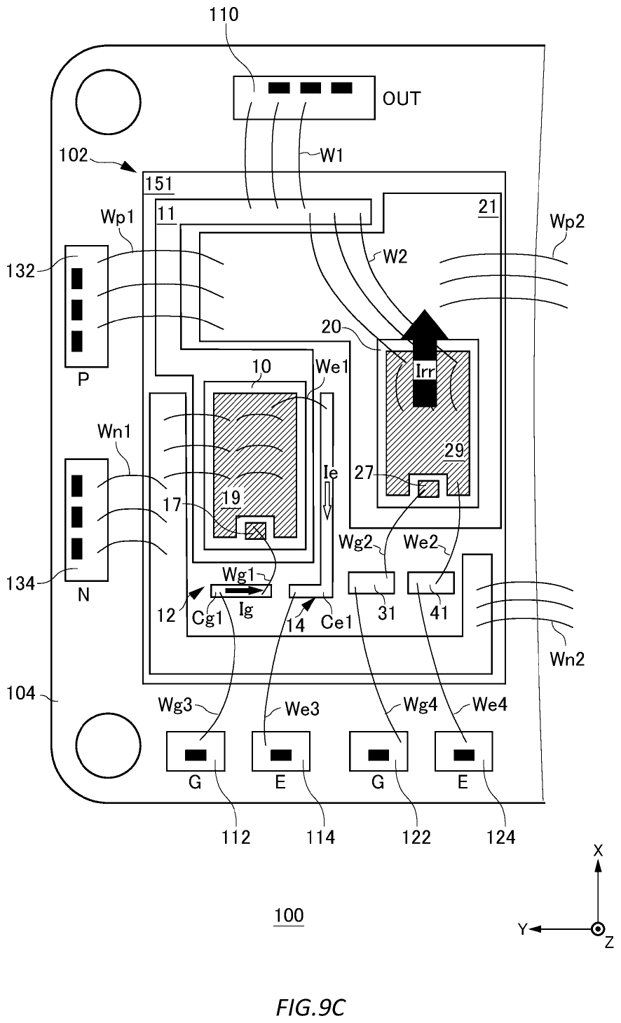

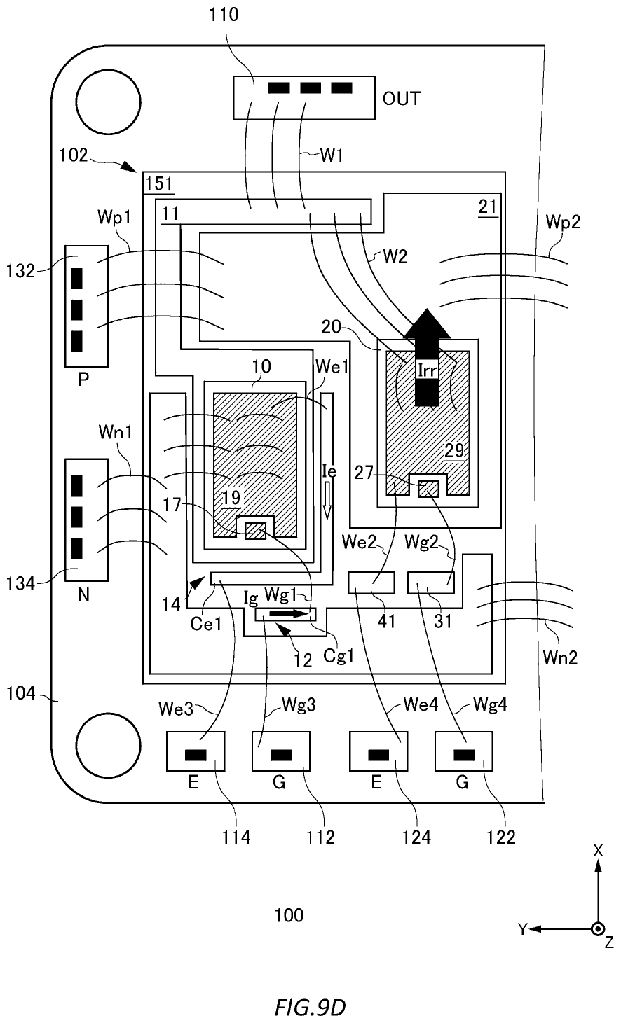

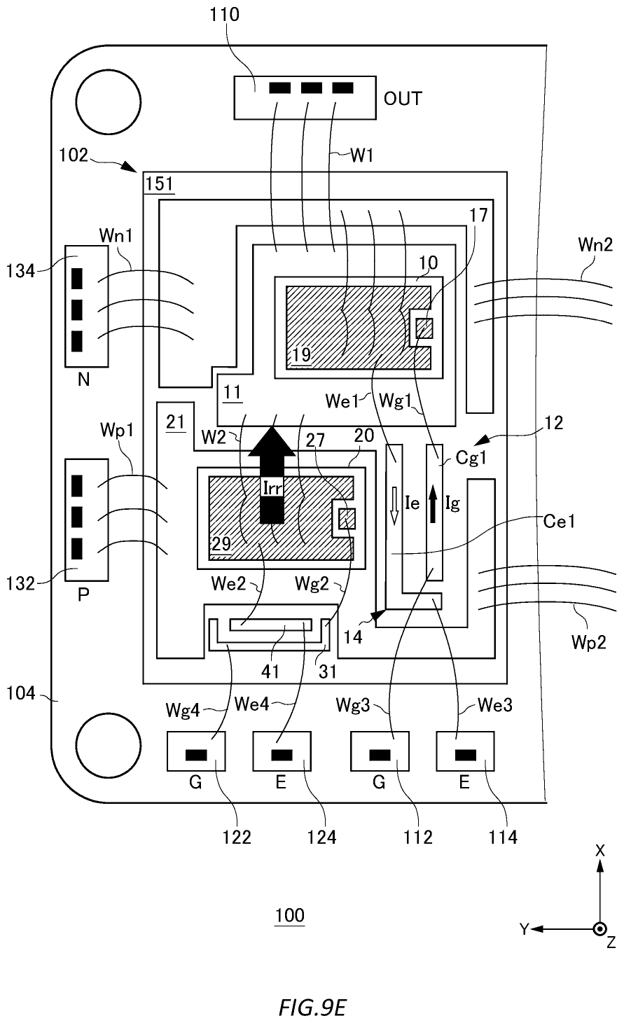

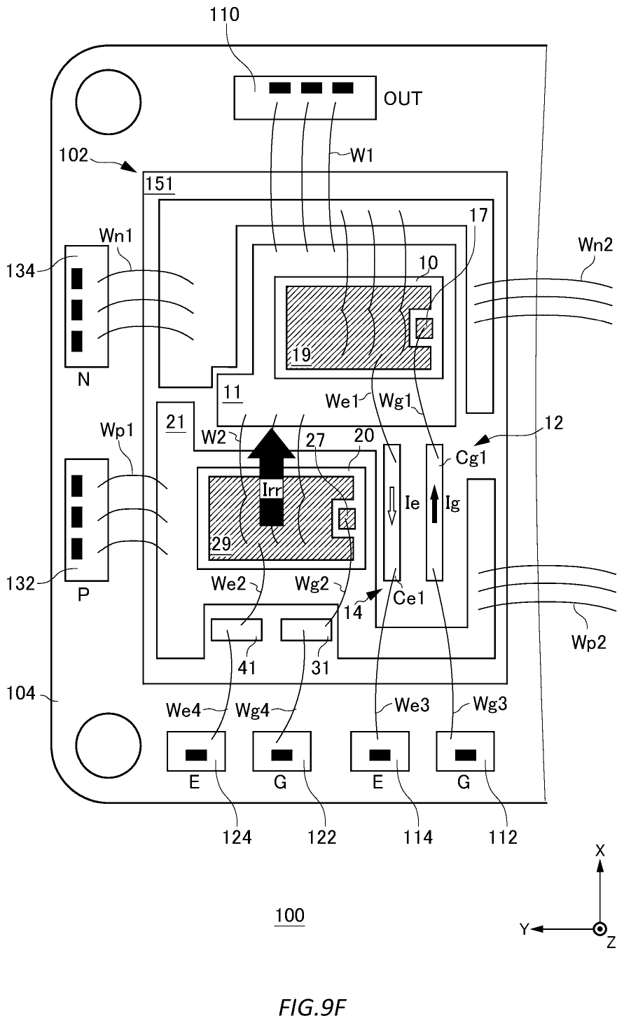

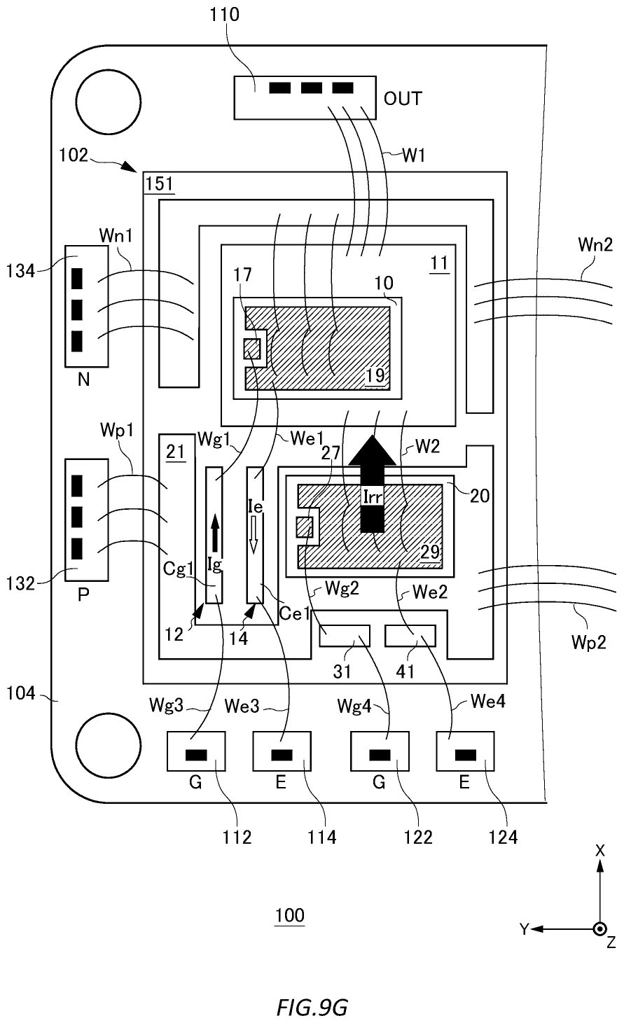

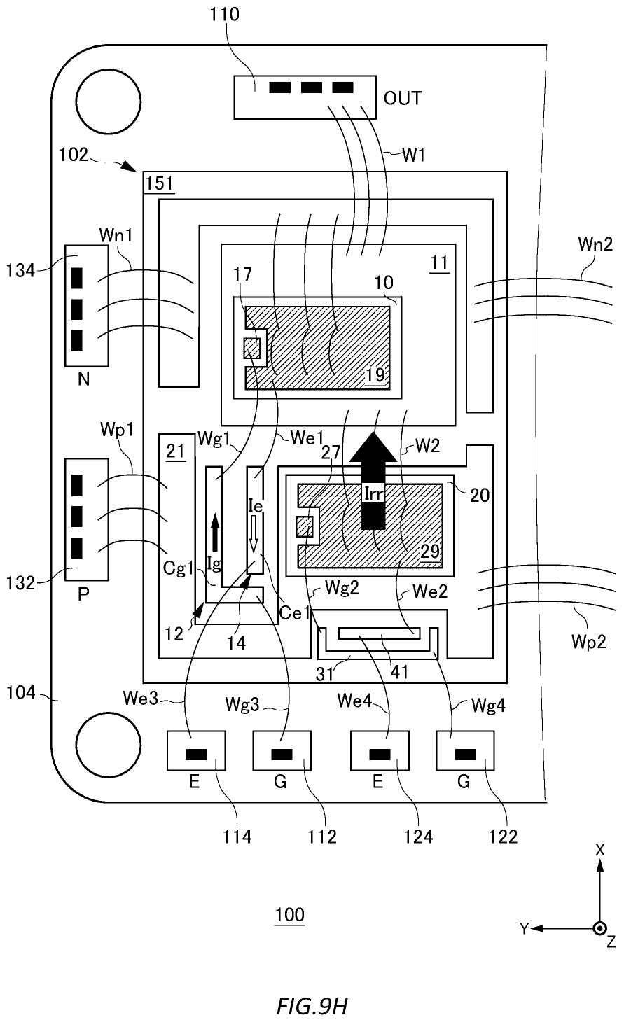

FIG. 9A is an enlarged view of a modification of the semiconductor assembly 102. The present example is different from the example of FIG. 1C in that the reverse recovery current Irr is generated in the upper arm when the switching element 10 arranged in the lower arm is energized. That is, the second circuit board 21 on which the switching element 20 is arranged is electrically connected to the positive electrode terminal 132. In the present example, points different from the example of FIG. 1C will be particularly described. The control terminals of the present example are arranged in the order of the gate external terminal 122, the auxiliary emitter external terminal 124, the gate external terminal 112, and the auxiliary emitter external terminal 114 toward the negative side in the Y-axis direction.

The gate circuit board Cg1 extends in the Y-axis direction. The auxiliary emitter circuit board Ce1 is arranged on the positive side in the X-axis direction with respect to the gate circuit board Cg1. The auxiliary emitter circuit board Ce1 of the present example has an L shape, but is not limited thereto. Regardless of the shape of the auxiliary emitter circuit board Ce1, the region in which the auxiliary emitter current Ie flows in antiparallel with the reverse recovery current Irr may be arranged to be closer to the switching element 20 than the region in which the auxiliary emitter current Ie flows in the direction orthogonal to the reverse recovery current Irr.

The auxiliary emitter wiring member 14 of the present example is provided to be closer to the switching element 20 than the gate wiring member 12. That is, the auxiliary emitter circuit board Ce1 is provided between the gate circuit board Cg1 and the switching element 20 in the XY plane. As described above, even when the reverse recovery current Irr is generated in the upper arm, the auxiliary emitter current Ie flowing through the auxiliary emitter wiring member 14 functioning as the first path member flows in antiparallel with the reverse recovery current Irr, and the current path is wired such that the gate current Ig and the auxiliary emitter current Ie increase as a whole.

FIG. 9B is an enlarged view of a modification of the semiconductor assembly 102. The present example is different from the example of FIG. 9A in that the control terminals are arranged in the order of EGEG. The control terminals of the present example are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 9A will be particularly described. The gate external terminal 112 of the present example is provided to be farther from the switching element 20 than the auxiliary emitter external terminal 114.

The gate circuit board Cg1 extends in the Y-axis direction on the negative side in the X-axis direction with respect to the switching element 10. The auxiliary emitter circuit board Ce1 is arranged between the gate circuit board Cg1 and the switching element 20. That is, the auxiliary emitter wiring member 14 is provided to be closer to the switching element 20 than the gate wiring member 12. The auxiliary emitter circuit board Ce1 of the present example has an L shape, but is not limited thereto. The gate wiring member 12 and the auxiliary emitter wiring member 14 of the present example are arranged in the order corresponding to the gate external terminal 112 and the auxiliary emitter external terminal 114 in the Y-axis direction, and are wired without crossing each other in the top view.

FIG. 9C is an enlarged view of a modification of the semiconductor assembly 102. The present example is different from the example of FIG. 9A in that the gate external terminal 112 and the auxiliary emitter external terminal 114 are arranged on the positive side in the Y-axis direction with respect to the gate external terminal 122 and the auxiliary emitter external terminal 124. The control terminals of the present example are arranged in the order of the gate external terminal 112, the auxiliary emitter external terminal 114, the gate external terminal 122, and the auxiliary emitter external terminal 124 toward the negative side in the Y-axis direction. The gate external terminal 112 of the present example is provided to be farther from the switching element 20 than the auxiliary emitter external terminal 114.

When the switching element 10 arranged in the lower arm is energized, the reverse recovery current Irr directed to the positive side in the X-axis direction is generated in the upper arm. On the other hand, in the auxiliary emitter circuit board Ce1, the auxiliary emitter current Ie directed to the negative side in the X-axis direction flows in the region close to the switching element 20. As described above, even when the arrangement of the control terminal and the switching element 20 is changed, the auxiliary emitter current Ie close to the switching element 20 flows in antiparallel with the reverse recovery current Irr, and the current path is wired such that the gate current Ig and the auxiliary emitter current Ie increase as a whole.

The auxiliary emitter circuit board Ce1 is arranged such that a region, in which the auxiliary emitter current Ie flows in antiparallel with the reverse recovery current Irr, in the L shape is closer to the switching element 20 than a region in which the auxiliary emitter current Ie flows in a direction orthogonal to the reverse recovery current Irr. Accordingly, the current path can be wired more flexibly while improving the switching speed at the time of turn-on. In the present example, a case where the auxiliary emitter current Ie antiparallel to the reverse recovery current Irr flows through the auxiliary emitter circuit board Ce1 has been described, but the same applies to a case where the gate current Ig antiparallel to the reverse recovery current Irr flows through the gate circuit board Cg1.

FIG. 9D is an enlarged view of a modification of the semiconductor assembly 102. The present example is different from the example of FIG. 9C in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 9C will be particularly described. The gate external terminal 112 of the present example is provided to be closer to the switching element 20 than the auxiliary emitter external terminal 114.

The gate circuit board Cg1 extends in the Y-axis direction on the negative side in the X-axis direction with respect to the switching element 10. The auxiliary emitter circuit board Ce1 is provided between the gate circuit board Cg1 and the switching element 20. The auxiliary emitter circuit board Ce1 of the present example has an L shape, but is not limited thereto. The circuit board 152 may be provided on the positive side of the switching element 10, the gate circuit board Cg1, and the auxiliary emitter circuit board Ce1 in the Y-axis direction. Accordingly, even in the relationship with the adjacent semiconductor assembly 102, the gate wiring member 12 and the auxiliary emitter wiring member 14 are arranged so as to avoid that the reverse recovery current Irr inhibits the flow of the gate current Ig or the auxiliary emitter current Ie.

In addition, since the gate circuit board Cg1 of the present example is provided to extend in the Y-axis direction, it is possible to avoid the influence of the reverse recovery current Irr generated in the adjacent semiconductor assembly 102. Similarly, in the auxiliary emitter circuit board Ce1, the L-shaped portion extending in the Y-axis direction is provided at the end of the semiconductor assembly 102, and the portion extending in the X-axis direction is provided at the center of the semiconductor assembly 102, so as to easily avoid the influence from the reverse recovery current Irr generated in the adjacent semiconductor assembly 102.

FIG. 9E is an enlarged view of a modification of the semiconductor assembly 102. The present example is different from the example of FIG. 9A in that the positions of the positive electrode terminal 132 and the negative electrode terminal 134 are exchanged. The positive electrode terminal 132 of the present example is arranged on the negative side in the X-axis direction with respect to the negative electrode terminal 134. In the present example, points different from the example of FIG. 9A will be particularly described.

The gate circuit board Cg1 extends in the X-axis direction on the negative side in the Y-axis direction with respect to the switching element 20. The auxiliary emitter circuit board Ce1 is provided between the gate circuit board Cg1 and the switching element 20. The auxiliary emitter circuit board Ce1 of the present example has an L shape, but is not limited thereto. Another circuit board 152 such as the second circuit board 21 may be provided on the negative side of the gate circuit board Cg1 and the auxiliary emitter circuit board Ce1 in the Y-axis direction.

The negative electrode terminal 134 of the present example is arranged on the positive side in the X-axis direction with respect to the positive electrode terminal 132, and when the switching element 10 arranged in the lower arm is energized, the reverse recovery current Irr directed to the positive side in the X-axis direction is generated in the upper arm. On the other hand, the auxiliary emitter current Ie directed to the negative side in the X-axis direction flows through the auxiliary emitter circuit board Ce1. Therefore, the auxiliary emitter current Ie close to the switching element 20 flows in antiparallel with the reverse recovery current Irr, and the current path is wired such that the gate current Ig and the auxiliary emitter current Ie increase as a whole.

FIG. 9F is an enlarged view of a modification of the semiconductor assembly 102. The present example is different from the example of FIG. 9E in that the control terminals are arranged in the order of EGEG. That is, the control terminals are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 9E will be particularly described. The gate external terminal 112 of the present example is provided to be farther from the switching element 20 than the auxiliary emitter external terminal 114.

The gate circuit board Cg1 extends in the X-axis direction on the negative side in the Y-axis direction with respect to the switching element 20. The auxiliary emitter circuit board Ce1 extends between the gate circuit board Cg1 and the switching element 20 in the X-axis direction. Another circuit board 152 such as the second circuit board 21 may be provided on the negative side of the gate circuit board Cg1 and the auxiliary emitter circuit board Ce1 in the Y-axis direction. The gate wiring member 12 and the auxiliary emitter wiring member 14 of the present example are arranged in the order corresponding to the gate external terminal 112 and the auxiliary emitter external terminal 114 in the Y-axis direction, and are wired without crossing each other in the top view.

The negative electrode terminal 134 of the present example is arranged on the positive side in the X-axis direction with respect to the positive electrode terminal 132, and when the switching element 10 arranged in the lower arm is energized, the reverse recovery current Irr directed to the positive side in the X-axis direction is generated in the upper arm. On the other hand, the auxiliary emitter current Ie directed to the negative side in the X-axis direction flows through the auxiliary emitter circuit board Ce1. Therefore, the auxiliary emitter current Ie close to the switching element 20 flows in antiparallel with the reverse recovery current Irr, and the current path is wired such that the gate current Ig and the auxiliary emitter current Ie increase as a whole.

FIG. 9G is an enlarged view of a modification of the semiconductor assembly 102. The present example is different from the example of FIG. 9E in that the gate external terminal 112 and the auxiliary emitter external terminal 114 are arranged on the positive side in the Y-axis direction with respect to the gate external terminal 122 and the auxiliary emitter external terminal 124. The control terminals of the present example are arranged in the order of the gate external terminal 112, the auxiliary emitter external terminal 114, the gate external terminal 122, and the auxiliary emitter external terminal 124 toward the negative side in the Y-axis direction. In the present example, points different from the example of FIG. 9E will be particularly described.

The gate circuit board Cg1 extends in the X-axis direction on the positive side in the Y-axis direction with respect to the switching element 20. The auxiliary emitter circuit board Ce1 extends between the gate circuit board Cg1 and the switching element 20 in the X-axis direction. Another circuit board 152 such as the second circuit board 21 may be provided on the positive side of the gate circuit board Cg1 and the auxiliary emitter circuit board Ce1 in the Y-axis direction.

When the switching element 10 arranged in the lower arm is energized, the reverse recovery current Irr directed to the positive side in the X-axis direction is generated in the upper arm. On the other hand, the auxiliary emitter current Ie directed to the negative side in the X-axis direction flows through the auxiliary emitter circuit board Ce1. As described above, even when the arrangement of the control terminal and the switching element 20 is changed, the auxiliary emitter current Ie close to the switching element 20 flows in antiparallel with the reverse recovery current Irr, and the current path is wired such that the gate current Ig and the auxiliary emitter current Ie increase as a whole.

FIG. 9H is an enlarged view of a modification of the semiconductor assembly 102. The present example is different from the example of FIG. 9G in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 9G will be particularly described.

The gate circuit board Cg1 is provided on the positive side in the Y-axis direction with respect to the switching element 20. The gate circuit board Cg1 of the present example has an L shape, but is not limited thereto. The auxiliary emitter circuit board Ce1 extends between the gate circuit board Cg1 and the switching element 20 in the X-axis direction. Another circuit board 152 such as the second circuit board 21 may be provided on the positive side of the gate circuit board Cg1 and the auxiliary emitter circuit board Ce1 in the Y-axis direction.

The auxiliary emitter wiring member 14 of the present example is provided to be closer to the switching element 20 than the gate wiring member 12. The gate wiring member 12 and the auxiliary emitter wiring member 14 of the present example may be wired to cross each other in the top view. Since the gate circuit board Cg1 has the L shape, the gate wiring member 12 and the auxiliary emitter wiring member 14 easily cross each other. In the present example, the gate circuit board Cg1 and the auxiliary emitter control wire We3 are wired to cross each other.

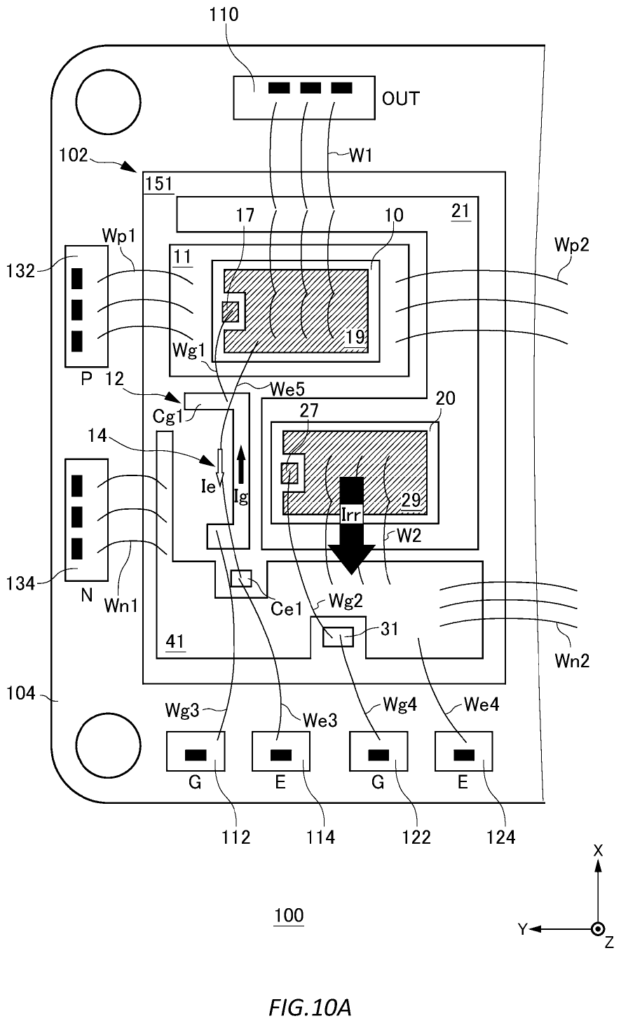

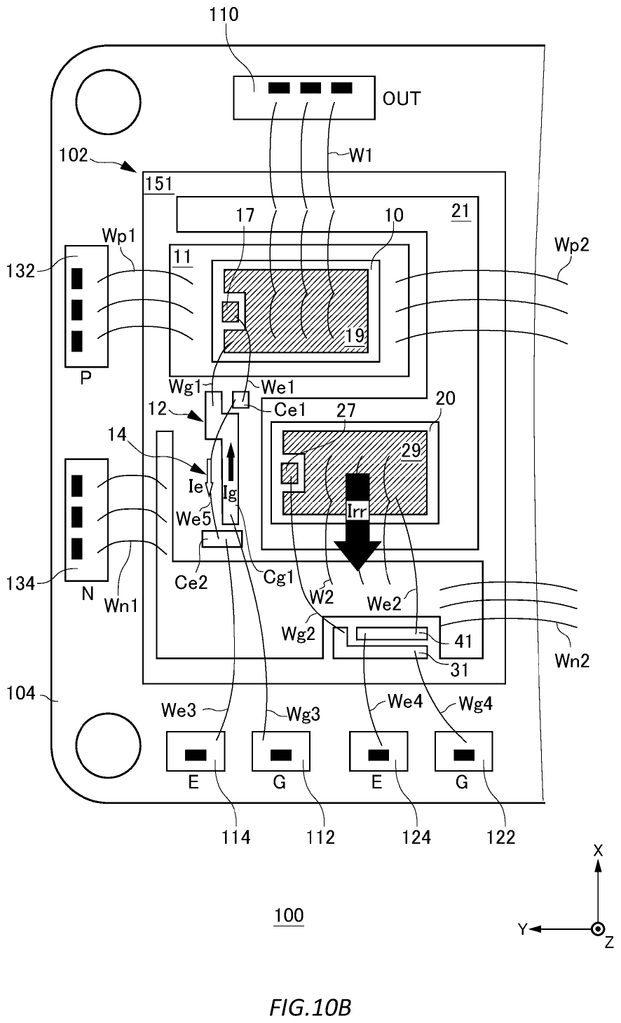

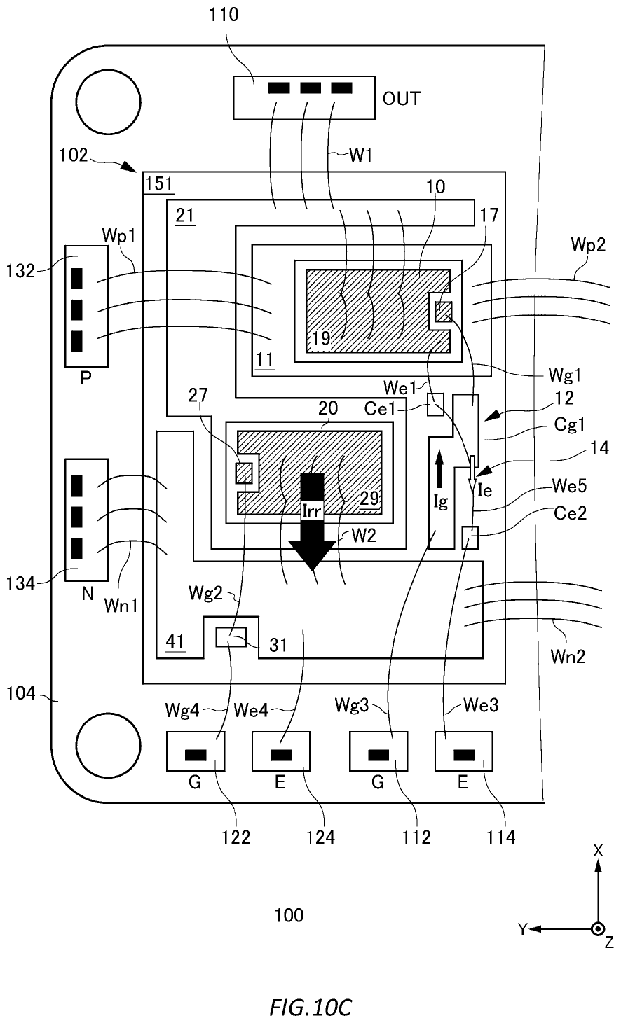

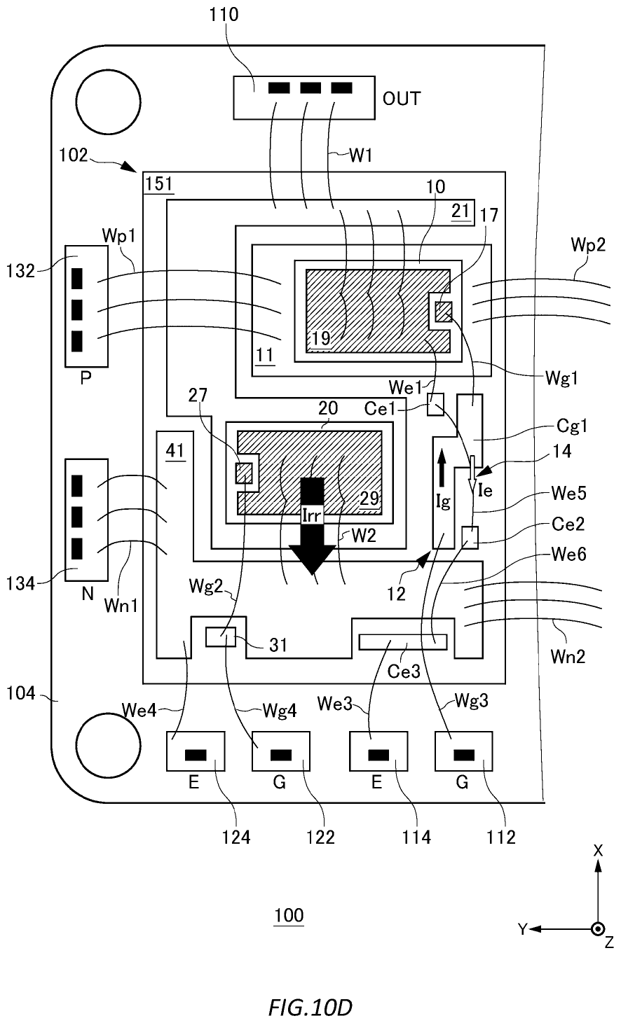

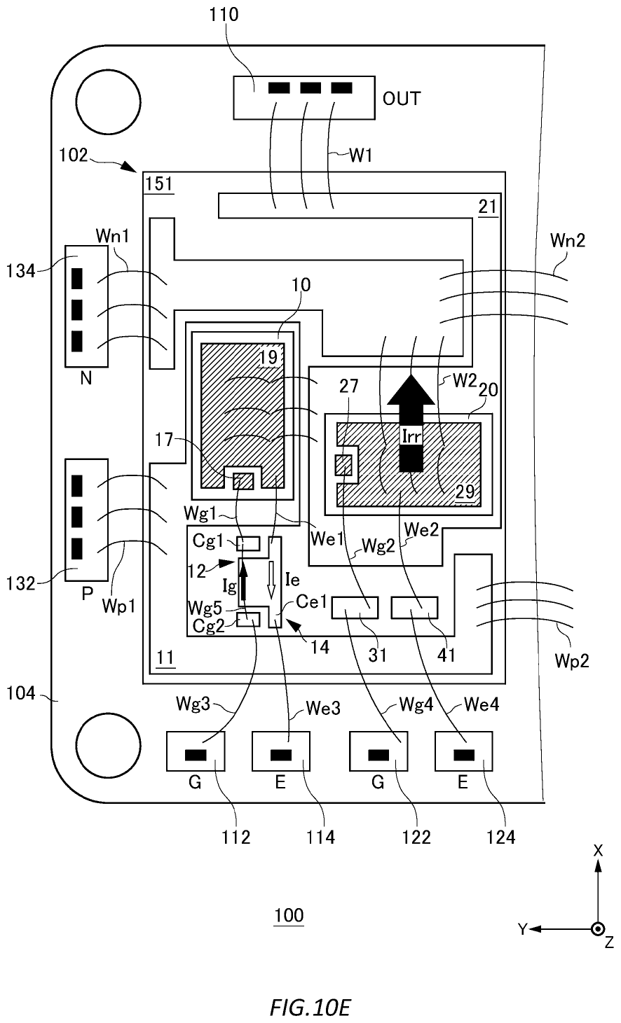

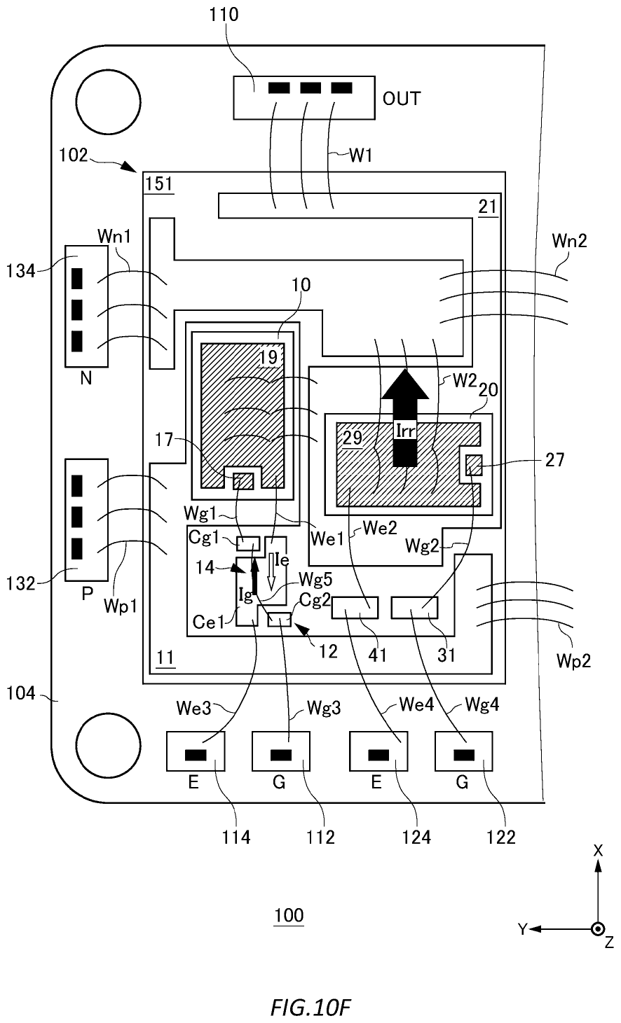

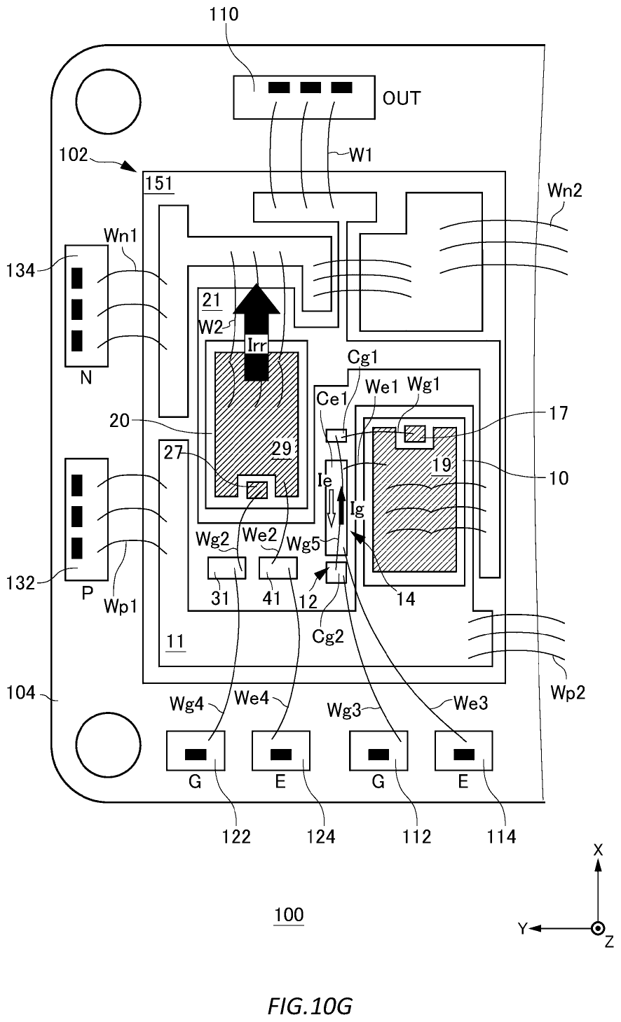

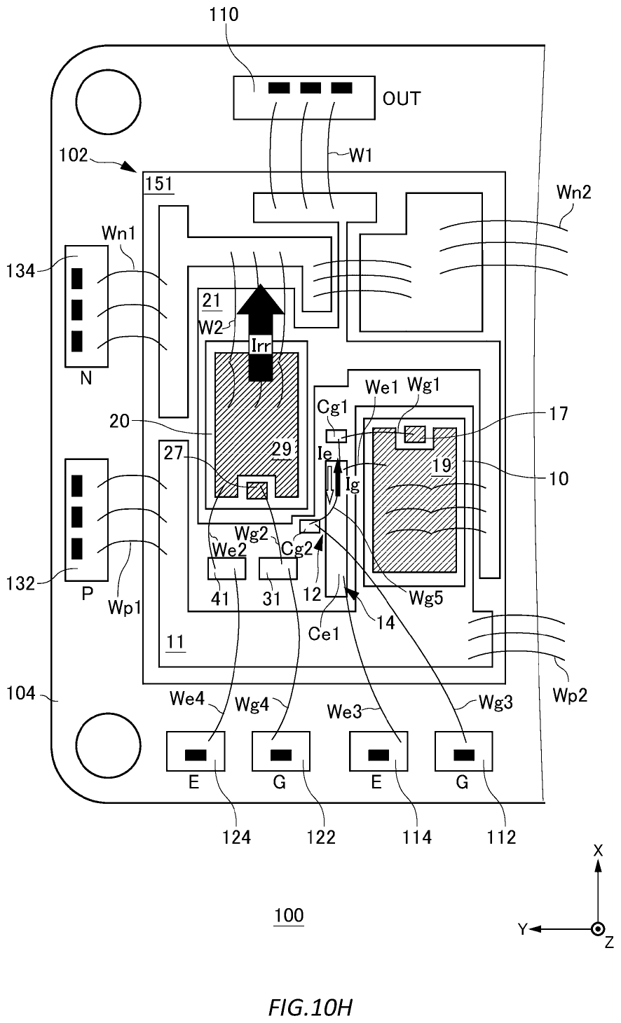

FIG. 10A is an enlarged view of a modification of the semiconductor assembly 102. The present example is different from the example of FIG. 1C in that in the region close to the switching element 20, one of the gate wiring member 12 and the auxiliary emitter wiring member 14 is constituted by the circuit board 152 and the other is constituted by a wire member. In the present example, points different from the example of FIG. 1C will be particularly described.

The gate wiring member 12 of the present example has the gate circuit board Cg1 at the position opposite to the reverse recovery current Irr. The auxiliary emitter wiring member 14 has an auxiliary emitter control wire We5 at the position opposite to the reverse recovery current Irr. The position opposite to the reverse recovery current Irr refers to, for example, a position extending in the direction in which the reverse recovery current Irr flows and opposite to the switching element 20 in the Y-axis direction. Note that at the position opposite to the reverse recovery current Irr, the gate wiring member 12 may have a wire member, and the auxiliary emitter wiring member 14 may have the auxiliary emitter circuit board Ce1.

The gate circuit board Cg1 is arranged on the positive side in the Y-axis direction with respect to the switching element 20. The gate circuit board Cg1 of the present example is provided between the auxiliary emitter control wire We5 and the switching element 20 in the top view. The gate circuit board Cg1 is provided to be closer to the switching element 20 than the auxiliary emitter control wire We5. The gate circuit board Cg1 has a substantially U shape, but is not limited thereto.

The auxiliary emitter control wire We5 is provided to extend substantially in the X-axis direction in the top view. The auxiliary emitter circuit board Ce1 is arranged on the negative side in the X-axis direction with respect to the gate circuit board Cg1. The auxiliary emitter control wire We5 is wired from the switching element 10 to the auxiliary emitter circuit board Ce1 over the upper side of the gate circuit board Cg1. The auxiliary emitter current Ie flows substantially in the X-axis direction in the auxiliary emitter control wire We5.

As described above, in the region close to the switching element 20, even when the member of the auxiliary emitter wiring member 14 is constituted by the auxiliary emitter control wire We5, similarly to other examples, the current flowing through the first path member close to the switching element 20 can be arranged in antiparallel with the reverse recovery current Irr. That is, whether the first path member and the second path member are close to the switching element 20 is not limited to within the XY plane, and may be decided in consideration of a three-dimensional space. In the auxiliary emitter wiring member 14 of the present example, the auxiliary emitter control wire We5 is arranged at the position opposite to the reverse recovery current Irr, so that the auxiliary emitter current Ie is moved above the circuit board 152, whereby the influence of the reverse recovery current Irr is more easily suppressed.

FIG. 10B is an enlarged view of a modification of the semiconductor assembly 102. The present example is different from the example of FIG. 10A in that the control terminals are arranged in the order of EGEG. The control terminals of the present example are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 10A will be particularly described. The gate external terminal 112 of the present example is provided to be closer to the switching element 20 than the auxiliary emitter external terminal 114.

The gate circuit board Cg1 is provided on the positive side in the Y-axis direction with respect to the switching element 20. The gate circuit board Cg1 of the present example extends in the X-axis direction, but may have a shape having a substantially S-shaped step. By arranging the gate circuit board Cg1 at the position opposite to the reverse recovery current Irr, the gate wiring member 12 of the present example becomes closer to the reverse recovery current Irr compared to the case of using a wire member, and the gate current Ig is easily strengthened by the mutually induced current Im1.

The auxiliary emitter wiring member 14 includes the auxiliary emitter control wire Wet, the auxiliary emitter circuit board Ce1, the auxiliary emitter control wire We5, an auxiliary emitter circuit board Ce2, and the auxiliary emitter control wire We3. The auxiliary emitter circuit board Ce1 and the auxiliary emitter circuit board Ce2 are arranged on the positive side in the Y-axis direction with respect to the switching element 20 with the gate circuit board Cg1 interposed therebetween. The auxiliary emitter control wire We5 is wired in the substantially X-axis direction from the auxiliary emitter circuit board Ce1 to the auxiliary emitter circuit board Ce2 over the upper side of the gate circuit board Cg1. The auxiliary emitter control wire We5 is provided to be farther from the switching element 20 than the gate circuit board Cg1.

The auxiliary emitter control wire We5 may cross the gate circuit board Cg1 in the top view. In the present example, in the region close to the reverse recovery current Irr, the gate circuit board Cg1 is wired such that the reverse recovery current Irr and the gate current Ig flow in antiparallel, and thus the gate current Ig can be strengthened by the reverse recovery current Irr. Accordingly, the gate current Ig and the auxiliary emitter current Ie easily increases as a whole, and the switching speed at the time of turn-on is easily improved.

FIG. 10C is an enlarged view of a modification of the semiconductor assembly 102. The present example is different from the example of FIG. 10A in that the gate external terminal 112 and the auxiliary emitter external terminal 114 are arranged on the negative side in the Y-axis direction with respect to the gate external terminal 122 and the auxiliary emitter external terminal 124. The control terminals of the present example are arranged in the order of the gate external terminal 122, the auxiliary emitter external terminal 124, the gate external terminal 112, and the auxiliary emitter external terminal 114 toward the negative side in the Y-axis direction. The gate external terminal 112 of the present example is provided to be closer to the switching element 20 than the auxiliary emitter external terminal 114.

The gate circuit board Cg1 is provided on the negative side in the Y-axis direction with respect to the switching element 20. The gate circuit board Cg1 of the present example extends in the X-axis direction, but may have a shape having a substantially S-shaped step. By arranging the gate circuit board Cg1 at the position opposite to the reverse recovery current Irr, the gate wiring member 12 of the present example becomes closer to the reverse recovery current Irr compared to the case of using a wire member, and the gate current Ig is easily strengthened by the mutually induced current Im1.

The auxiliary emitter wiring member 14 includes the auxiliary emitter control wire Wet, the auxiliary emitter circuit board Ce1, the auxiliary emitter control wire We5, an auxiliary emitter circuit board Ce2, and the auxiliary emitter control wire We3. The auxiliary emitter circuit board Ce1 and the auxiliary emitter circuit board Ce2 are arranged on the negative side in the Y-axis direction with respect to the switching element 20 with the gate circuit board Cg1 interposed therebetween. The auxiliary emitter control wire We5 is wired in the substantially X-axis direction from the auxiliary emitter circuit board Ce1 to the auxiliary emitter circuit board Ce2 over the upper side of the gate circuit board Cg1. The auxiliary emitter control wire We5 is provided to be farther from the switching element 20 than the gate circuit board Cg1.

When the switching element 10 arranged in the upper arm is energized, the reverse recovery current Irr directed to the negative side in the X-axis direction is generated in the lower arm. On the other hand, in the gate circuit board Cg1, the gate current Ig directed to the positive side in the X-axis direction flows in the region close to the switching element 20. As described above, even when the arrangement of the control terminal and the switching element 20 is changed, the gate current Ig close to the switching element 20 flows in antiparallel with the reverse recovery current Irr, and the current path is wired such that the gate current Ig and the auxiliary emitter current Ie increase as a whole.

FIG. 10D is an enlarged view of a modification of the semiconductor assembly 102. The present example is different from the example of FIG. 10C in that the control terminals are arranged in the order of EGEG. That is, the control terminals are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 10C will be particularly described. The gate external terminal 112 of the present example is provided to be farther from the switching element 20 than the auxiliary emitter external terminal 114.

The gate circuit board Cg1 is provided on the negative side in the X-axis direction with respect to the switching element 10. The gate circuit board Cg1 of the present example extends in the X-axis direction, but may have a shape having a substantially S-shaped step.

The auxiliary emitter wiring member 14 includes the auxiliary emitter control wire We1, the auxiliary emitter circuit board Ce1, the auxiliary emitter control wire We5, the auxiliary emitter circuit board Ce2, an auxiliary emitter control wire We6, an auxiliary emitter circuit board Ce3, and the auxiliary emitter control wire We3. The auxiliary emitter circuit board Ce1 and the auxiliary emitter circuit board Ce2 are arranged on the negative side in the Y-axis direction with respect to the switching element 20 with the gate circuit board Cg1 interposed therebetween.

The auxiliary emitter control wire We5 is wired in the substantially X-axis direction from the auxiliary emitter circuit board Ce1 to the auxiliary emitter circuit board Ce2 over the upper side of the gate circuit board Cg1. The auxiliary emitter circuit board Ce3 is arranged on the negative side in the X-axis direction with respect to the auxiliary emitter circuit board Ce2 with the fourth circuit board 41 interposed therebetween. The auxiliary emitter control wire We6 is wired from the auxiliary emitter circuit board Ce2 to the auxiliary emitter circuit board Ce3 over the upper side of the fourth circuit board 41.

FIG. 10E is an enlarged view of a modification of the semiconductor assembly 102. The present example is different from the example of FIG. 10A in that the positions of the positive electrode terminal 132 and the negative electrode terminal 134 are exchanged. The positive electrode terminal 132 of the present example is arranged on the negative side in the X-axis direction with respect to the negative electrode terminal 134. In the present example, points different from the example of FIG. 10A will be particularly described.

The gate wiring member 12 includes the gate control wire Wg1, the gate circuit board Cg1, a gate control wire Wg5, a gate circuit board Cg2, and the gate control wire Wg3. The gate circuit board Cg1 and the gate circuit board Cg2 are arranged on the positive side in the Y-axis direction with respect to the switching element 20 with the auxiliary emitter circuit board Ce1 interposed therebetween. The gate control wire Wg5 is provided to extend in the X-axis direction over the upper side of the auxiliary emitter circuit board Ce1. The circuit board 152 such as the first circuit board 11 may be arranged on the positive side of the gate circuit board Cg1 and the gate circuit board Cg2 in the Y-axis direction.

The negative electrode terminal 134 of the present example is arranged on the positive side in the X-axis direction with respect to the positive electrode terminal 132, and when the switching element 10 arranged in the upper arm is energized, the reverse recovery current Irr directed to the positive side in the X-axis direction is generated in the lower arm. On the other hand, the auxiliary emitter current Ie directed to the negative side in the X-axis direction flows through the auxiliary emitter circuit board Ce1. Therefore, the auxiliary emitter current Ie close to the switching element 20 flows in antiparallel with the reverse recovery current Irr, and the current path is wired such that the gate current Ig and the auxiliary emitter current Ie increase as a whole.

FIG. 10F is an enlarged view of a modification of the semiconductor assembly 102. The present example is different from the example of FIG. 10E in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 10E will be particularly described. The gate external terminal 112 of the present example is provided to be closer to the switching element 20 than the auxiliary emitter external terminal 114.

The gate circuit board Cg1 and the gate circuit board Cg2 are arranged with the auxiliary emitter circuit board Ce1 interposed therebetween. The gate control wire Wg5 is wired to extend in the substantially X-axis direction over the upper side of the auxiliary emitter circuit board Ce1. The auxiliary emitter circuit board Ce1 has a region closer to the switching element 20 than the gate control wire Wg5. In the region of the auxiliary emitter circuit board Ce1 close to the switching element 20, the auxiliary emitter current Ie flows in antiparallel with the reverse recovery current Irr, and the current path is wired such that the gate current Ig and the auxiliary emitter current Ie increase as a whole.

In addition, in the present example, the gate control wire Wg1 and the auxiliary emitter control wire We1 are arranged at the positions opposite to the reverse recovery current Irr. The auxiliary emitter control wire We1 allows the auxiliary emitter current Ie to flow in antiparallel with the reverse recovery current Irr, and is provided to be closer to the switching element 20 than the gate control wire Wg1. Accordingly, the auxiliary emitter current Ie flowing through the auxiliary emitter wiring member 14 can be strengthened.

FIG. 10G is an enlarged view of a modification of the semiconductor assembly 102. The present example is different from the example of FIG. 10E in that the gate external terminal 112 and the auxiliary emitter external terminal 114 are arranged on the negative side in the Y-axis direction with respect to the gate external terminal 122 and the auxiliary emitter external terminal 124. The control terminals of the present example are arranged in the order of the gate external terminal 122, the auxiliary emitter external terminal 124, the gate external terminal 112, and the auxiliary emitter external terminal 114 toward the negative side in the Y-axis direction. In the present example, points different from the example of FIG. 10E will be particularly described.

The gate circuit board Cg1 and the gate circuit board Cg2 are arranged on the negative side in the Y-axis direction with respect to the switching element 20 with the auxiliary emitter circuit board Ce1 interposed therebetween. The auxiliary emitter circuit board Ce1 extends in the X-axis direction on the negative side in the Y-axis direction with respect to the switching element 20. The auxiliary emitter circuit board Ce1 of the present example has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

FIG. 10H is an enlarged view of a modification of the semiconductor assembly 102. The present example is different from the example of FIG. 10G in that the control terminals are arranged in the order of EGEG. That is, the control terminals are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 10G will be particularly described.

The gate circuit board Cg1 is arranged between the switching element 10 and the switching element 20. The gate circuit board Cg2 is arranged on the negative side in the X-axis direction with respect to the switching element 20. The auxiliary emitter circuit board Ce1 extends between the gate circuit board Cg2 and the switching element 10 in the X-axis direction. The circuit board 152 such as the second circuit board 21 may be provided on the negative side of the switching element 10 in the Y-axis direction. The circuit board 152 such as the first circuit board 11 may be provided on the positive side of the switching element 20 in the Y-axis direction.

The auxiliary emitter circuit board Ce1 of the present example has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

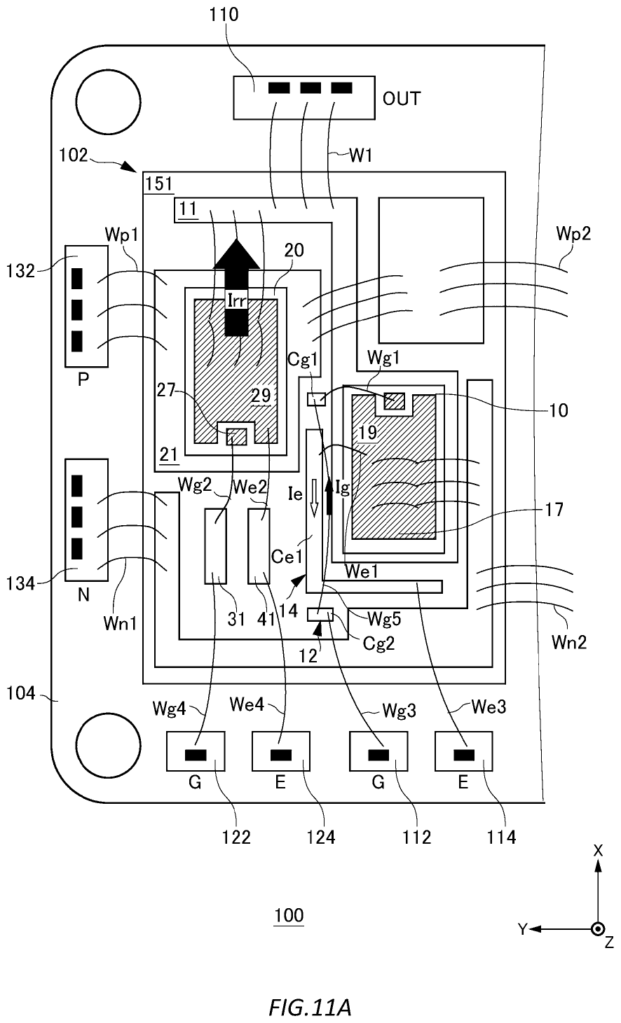

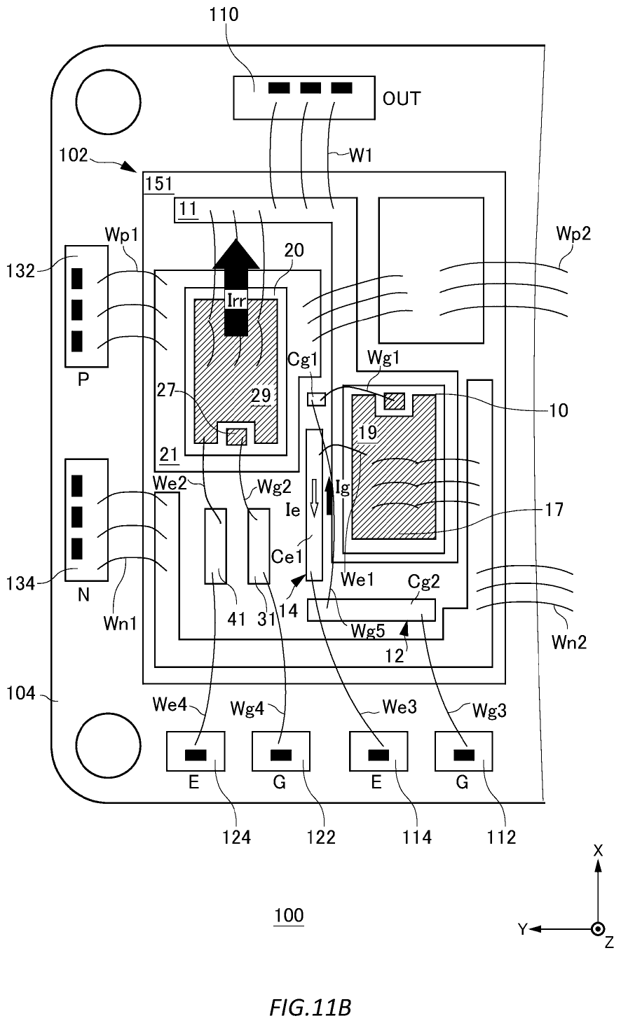

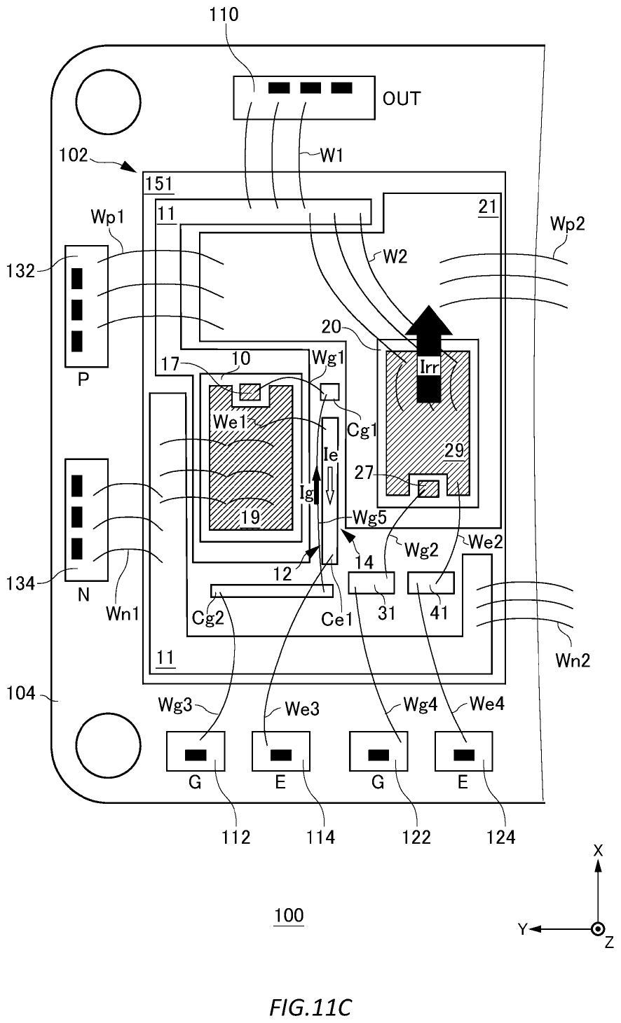

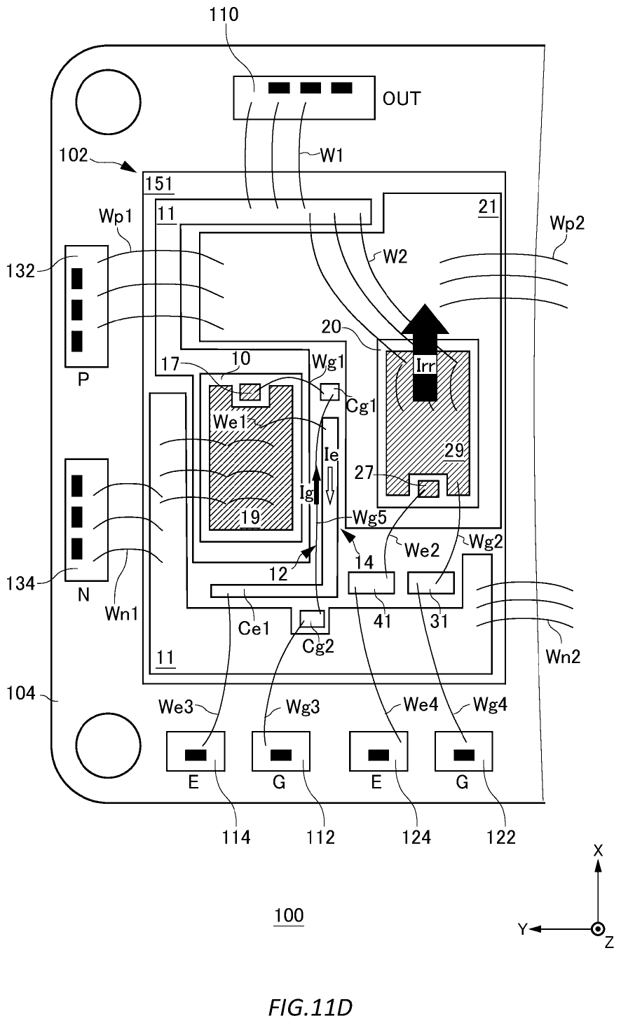

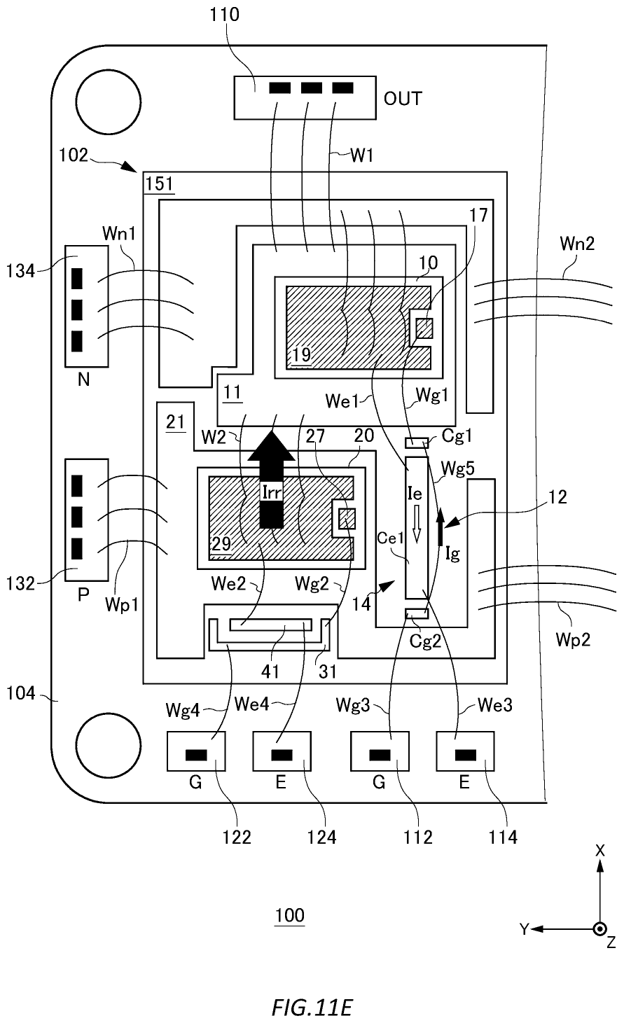

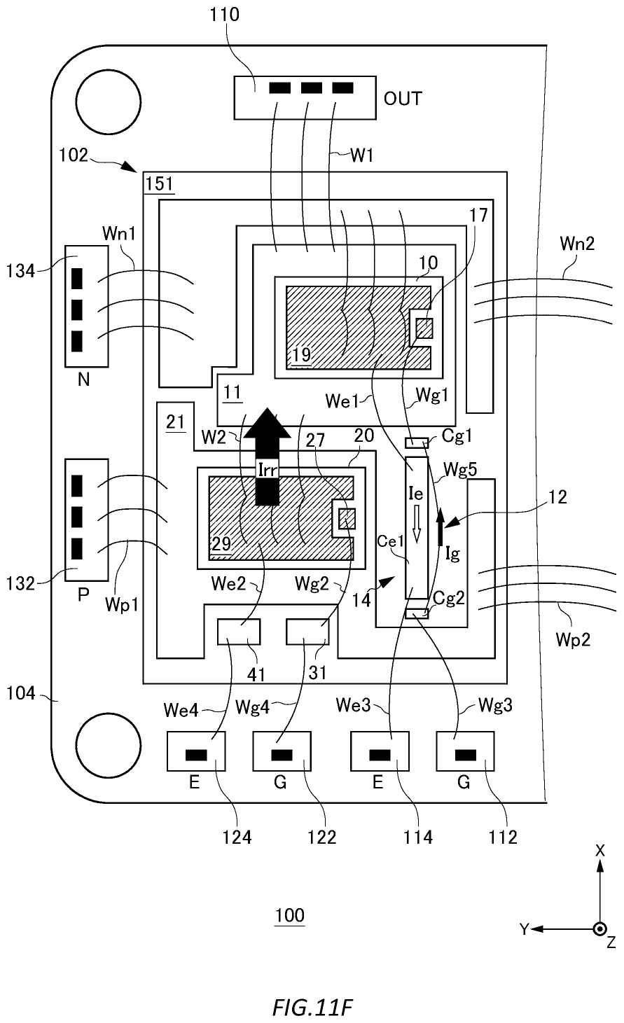

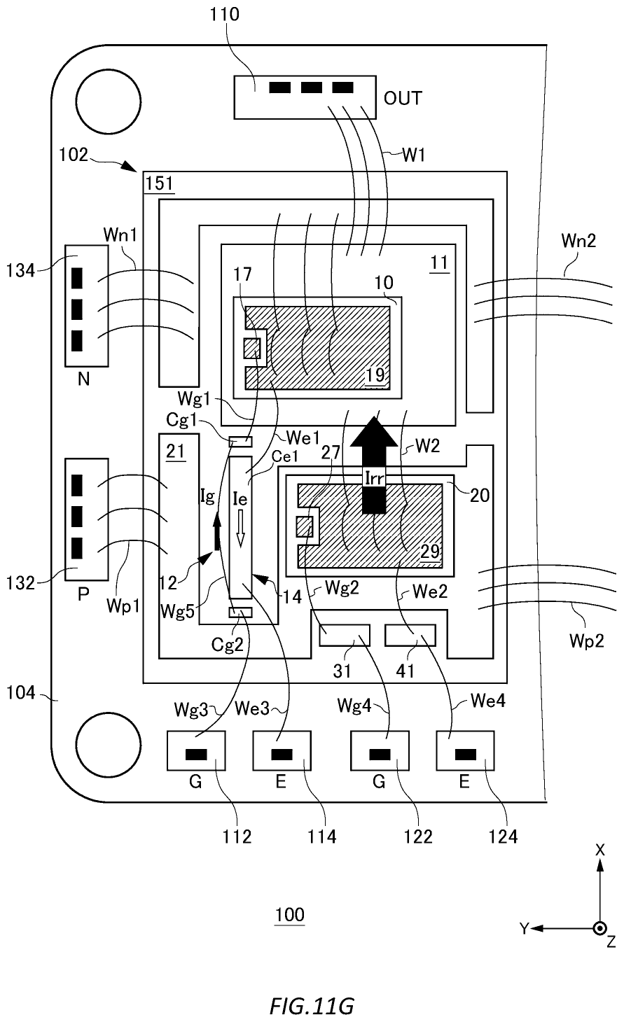

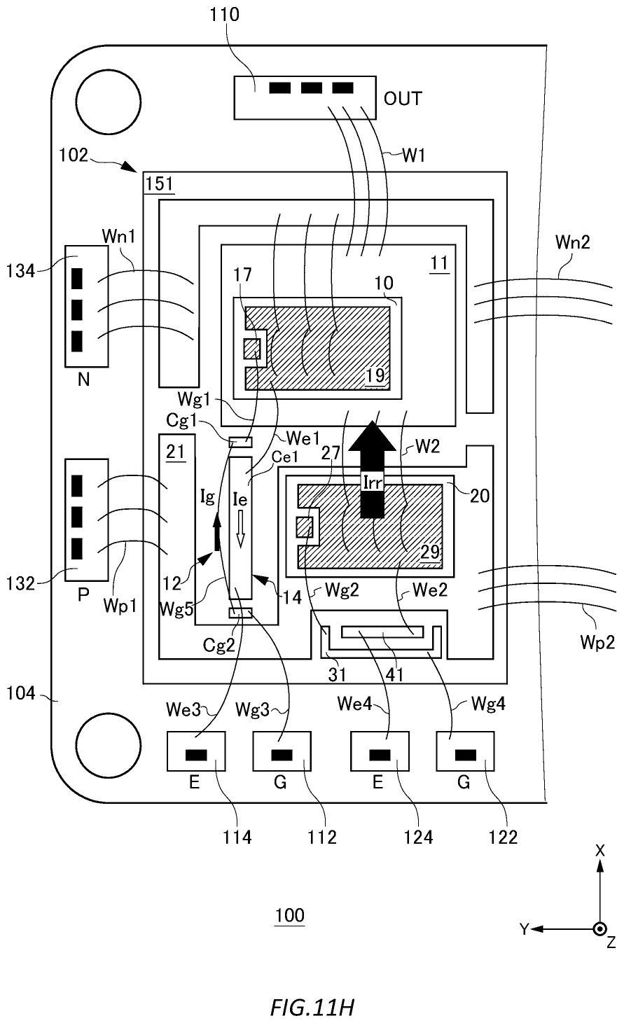

FIG. 11A is an enlarged view of a modification of the semiconductor assembly 102. The present example is different from the example of FIG. 10A in that the reverse recovery current Irr is generated in the upper arm when the switching element 10 arranged in the lower arm is energized. That is, the second circuit board 21 on which the switching element 20 is arranged is electrically connected to the positive electrode terminal 132. In the present example, points different from the example of FIG. 10A will be particularly described. The control terminals of the present example are arranged in the order of the gate external terminal 122, the auxiliary emitter external terminal 124, the gate external terminal 112, and the auxiliary emitter external terminal 114 toward the negative side in the Y-axis direction.

The gate circuit board Cg1 and the gate circuit board Cg2 are provided with the auxiliary emitter circuit board Ce1 interposed therebetween. The auxiliary emitter circuit board Ce1 is provided on the negative side in the Y-axis direction with respect to the switching element 20. The auxiliary emitter circuit board Ce1 of the present example has an L shape, but is not limited thereto. The auxiliary emitter circuit board Ce1 has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

FIG. 11B is an enlarged view of a modification of the semiconductor assembly 102. The present example is different from the example of FIG. 11A in that the control terminals are arranged in the order of EGEG. The control terminals of the present example are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 11A will be particularly described. The gate external terminal 112 of the present example is provided to be farther from the switching element 20 than the auxiliary emitter external terminal 114.

The gate circuit board Cg1 and the gate circuit board Cg2 are provided with the auxiliary emitter circuit board Ce1 interposed therebetween. The gate circuit board Cg2 of the present example extends to the negative side in the Y-axis direction up to the vicinity of the gate external terminal 112 in order to be connected to the gate external terminal 112 by the gate control wire Wg3.

The auxiliary emitter circuit board Ce1 extends in the X-axis direction on the negative side in the Y-axis direction with respect to the switching element 20. The auxiliary emitter circuit board Ce1 has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

FIG. 11C is an enlarged view of a modification of the semiconductor assembly 102. The present example is different from the example of FIG. 11A in that the gate external terminal 112 and the auxiliary emitter external terminal 114 are arranged on the positive side in the Y-axis direction with respect to the gate external terminal 122 and the auxiliary emitter external terminal 124. The control terminals of the present example are arranged in the order of the gate external terminal 112, the auxiliary emitter external terminal 114, the gate external terminal 122, and the auxiliary emitter external terminal 124 toward the negative side in the Y-axis direction. The gate external terminal 112 of the present example is provided to be farther from the switching element 20 than the auxiliary emitter external terminal 114.

The gate circuit board Cg1 and the gate circuit board Cg2 are provided on the positive side in the Y-axis direction with respect to the switching element 20 with the auxiliary emitter circuit board Ce1 interposed therebetween. The gate circuit board Cg2 of the present example extends to the positive side in the Y-axis direction up to the vicinity of the gate external terminal 112 in order to be connected to the gate external terminal 112 by the gate control wire Wg3.

The auxiliary emitter circuit board Ce1 extends in the X-axis direction on the positive side in the Y-axis direction with respect to the switching element 20. The auxiliary emitter circuit board Ce1 has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

FIG. 11D is an enlarged view of a modification of the semiconductor assembly 102. The present example is different from the example of FIG. 11C in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 11C will be particularly described. The gate external terminal 112 of the present example is provided to be closer to the switching element 20 than the auxiliary emitter external terminal 114.

The auxiliary emitter circuit board Ce1 is provided on the positive side in the Y-axis direction with respect to the switching element 20. The auxiliary emitter circuit board Ce1 of the present example has an L shape, but is not limited thereto. The auxiliary emitter circuit board Ce1 has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

FIG. 11E is an enlarged view of a modification of the semiconductor assembly 102. The present example is different from the example of FIG. 11A in that the positions of the positive electrode terminal 132 and the negative electrode terminal 134 are exchanged. The positive electrode terminal 132 of the present example is arranged on the negative side in the X-axis direction with respect to the negative electrode terminal 134. In the present example, points different from the example of FIG. 11A will be particularly described.

The gate circuit board Cg1 and the gate circuit board Cg2 are arranged on the negative side in the Y-axis direction with respect to the switching element 20 with the auxiliary emitter circuit board Ce1 interposed therebetween. The auxiliary emitter circuit board Ce1 extends in the X-axis direction on the negative side in the Y-axis direction with respect to the switching element 20. The gate control wire Wg5 is provided to extend in the substantially X-axis direction over the upper side of the auxiliary emitter circuit board Ce1. The circuit board 152 such as the second circuit board 21 may be arranged on the negative side of the gate circuit board Cg1 and the gate circuit board Cg2 in the Y-axis direction.

The negative electrode terminal 134 of the present example is arranged on the positive side in the X-axis direction with respect to the positive electrode terminal 132, and when the switching element 10 arranged in the lower arm is energized, the reverse recovery current Irr directed to the positive side in the X-axis direction is generated in the upper arm. On the other hand, the auxiliary emitter current Ie directed to the negative side in the X-axis direction flows through the auxiliary emitter circuit board Ce1. Therefore, the auxiliary emitter current Ie close to the switching element 20 flows in antiparallel with the reverse recovery current Irr, and the current path is wired such that the gate current Ig and the auxiliary emitter current Ie increase as a whole.

FIG. 11F is an enlarged view of a modification of the semiconductor assembly 102. The present example is different from the example of FIG. 11E in that the control terminals are arranged in the order of EGEG. That is, the control terminals are arranged in the order of the auxiliary emitter external terminal 124, the gate external terminal 122, the auxiliary emitter external terminal 114, and the gate external terminal 112 toward the negative side in the Y-axis direction. In the present example, points different from the example of FIG. 11E will be particularly described. The gate external terminal 112 of the present example is provided to be farther from the switching element 20 than the auxiliary emitter external terminal 114.

The gate circuit board Cg1 and the gate circuit board Cg2 are arranged on the negative side in the Y-axis direction with respect to the switching element 20 with the auxiliary emitter circuit board Ce1 interposed therebetween. The auxiliary emitter circuit board Ce1 extends in the X-axis direction on the negative side in the Y-axis direction with respect to the switching element 20. The auxiliary emitter circuit board Ce1 has a region closer to the switching element 20 than the gate control wire Wg5. In the region of the auxiliary emitter circuit board Ce1 close to the switching element 20, the auxiliary emitter current Ie flows in antiparallel with the reverse recovery current Irr, and the current path is wired such that the gate current Ig and the auxiliary emitter current Ie increase as a whole.

FIG. 11G is an enlarged view of a modification of the semiconductor assembly 102. The present example is different from the example of FIG. 11E in that the gate external terminal 112 and the auxiliary emitter external terminal 114 are arranged on the positive side in the Y-axis direction with respect to the gate external terminal 122 and the auxiliary emitter external terminal 124. The control terminals of the present example are arranged in the order of the gate external terminal 112, the auxiliary emitter external terminal 114, the gate external terminal 122, and the auxiliary emitter external terminal 124 toward the negative side in the Y-axis direction. In the present example, points different from the example of FIG. 11E will be particularly described.

The gate circuit board Cg1 and the gate circuit board Cg2 are arranged on the positive side in the Y-axis direction with respect to the switching element 20 with the auxiliary emitter circuit board Ce1 interposed therebetween. The auxiliary emitter circuit board Ce1 extends in the X-axis direction on the positive side in the Y-axis direction with respect to the switching element 20. The auxiliary emitter circuit board Ce1 of the present example has a region closer to the switching element 20 than the gate control wire Wg5. In the region of the auxiliary emitter circuit board Ce1 closer to the switching element 20 than the gate control wire Wg5, the auxiliary emitter current Ie flows in antiparallel with the reverse recovery current Irr, and the current path is wired such that the gate current Ig and the auxiliary emitter current Ie increase as a whole.

FIG. 11H is an enlarged view of a modification of the semiconductor assembly 102. The present example is different from the example of FIG. 11G in that the control terminals are arranged in the order of EGEG. That is, the control terminals are arranged in the order of the auxiliary emitter external terminal 114, the gate external terminal 112, the auxiliary emitter external terminal 124, and the gate external terminal 122 toward the negative side in the Y-axis direction. In the present example, points different from the example of FIG. 11G will be particularly described.

The gate circuit board Cg1 and the gate circuit board Cg2 are arranged on the positive side in the Y-axis direction with respect to the switching element 20. The auxiliary emitter circuit board Ce1 extends between the gate circuit board Cg1 and the gate circuit board Cg2 in the X-axis direction. The circuit board 152 such as the second circuit board 21 may be provided on the positive side of the auxiliary emitter circuit board Ce2 in the Y-axis direction. The circuit board 152 such as the second circuit board 21 may be provided on the negative side of the switching element 20 in the Y-axis direction.

While the embodiment of the present invention has been described, the technical scope of the invention is not limited to the above-described embodiment. It is apparent to persons skilled in the art that various alterations and improvements can be added to the above described embodiments. It is also apparent from the description of the claims that embodiments added with such alterations or improvements can be included in the technical scope of the present invention.

The operations, procedures, steps, and stages of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: switching element; 11: first circuit board; 12: gate wiring member; 14: auxiliary emitter wiring member; 17: gate electrode; 19: emitter electrode; 20: switching element; 21: second circuit board; 27: gate electrode; 29: emitter electrode; 31: third circuit board; 41: fourth circuit board; 100: semiconductor module; 102: semiconductor assembly; 104: housing; 110: output terminal; 112: gate external terminal; 114: auxiliary emitter external terminal; 122: gate external terminal; 124: auxiliary emitter external terminal; 132: positive electrode terminal; 134: negative electrode terminal; 150: laminated substrate; 151: insulating plate; 152: circuit board; 153: metal plate; 200: load; 210: drive unit; 500: semiconductor module; 512: gate wiring member; 514: auxiliary emitter wiring member.

What is claimed is:

1. A semiconductor module comprising:
a reverse conducting first switching element which is provided on one of an upper arm and a lower arm;
a reverse conducting second switching element which is provided on another of the upper arm and the lower arm;
a first path member which is electrically connected to one of a gate electrode and an emitter electrode of the first switching element; and
a second path member which is electrically connected to another of the gate electrode and the emitter electrode of the first switching element, wherein
the first path member is provided to be closer to the second switching element than the second path member,
current flowing through the first path member flows in antiparallel with a reverse recovery current of an arm provided with the second switching element, and
the first path member, the first switching element, and the second switching element are arranged on a same insulating substrate.

2. The semiconductor module according to claim 1, wherein
the first path member is a gate wiring member electrically connected to the gate electrode of the first switching element, and
the second path member is an auxiliary emitter wiring member electrically connected to the emitter electrode of the first switching element.

3. The semiconductor module according to claim 1, wherein
the first path member is an auxiliary emitter wiring member electrically connected to the emitter electrode of the first switching element, and
the second path member is a gate wiring member electrically connected to the gate electrode of the first switching element.

4. The semiconductor module according to claim 1, wherein
the first path member and the second path member have a conductive circuit board, and
the circuit board of the first path member is provided between the circuit board of the second path member and the second switching element in a top view.

5. The semiconductor module according to claim 1, wherein
the first path member has a conductive circuit board,
the second path member has a conductive wire member, and
the circuit board of the first path member is provided to be closer to the second switching element than the wire member of the second path member.

6. The semiconductor module according to claim 1, comprising:
a gate external terminal which is electrically connected to the gate electrode of the first switching element via the first path member or the second path member; and
an auxiliary emitter external terminal which is electrically connected to the emitter electrode of the first switching element via the first path member or the second path member, wherein
the gate external terminal is provided to be closer to the second switching element than the auxiliary emitter external terminal.

7. The semiconductor module according to claim 1, comprising:
a gate external terminal which is electrically connected to the gate electrode of the first switching element via the first path member or the second path member; and
an auxiliary emitter external terminal which is electrically connected to the emitter electrode of the first switching element via the first path member or the second path member, wherein
the gate external terminal is provided to be farther from the second switching element than the auxiliary emitter external terminal.

8. The semiconductor module according to claim 6, comprising:
an output terminal which is provided on one predetermined side of the semiconductor module, wherein
the gate external terminal and the auxiliary emitter external terminal are provided on a side opposite to the side on which the output terminal is provided.

9. The semiconductor module according to claim 6, comprising:
a positive electrode terminal and a negative electrode terminal which are provided on one predetermined side of the semiconductor module, wherein
the positive electrode terminal and the negative electrode terminal are provided on a side orthogonal to a side on which the gate external terminal and the auxiliary emitter external terminal are provided.

10. The semiconductor module according to claim 1, wherein
each of the first switching element and the second switching element is constituted by one chip.

11. The semiconductor module according to claim 10, wherein
the first switching element and the second switching element are any one of an RC-IGBT, an element in which a SiC-MOS and a SiC-SBD are integrated, or an element in which a body diode of the SiC-MOS is caused to function as a freewheeling diode.

12. The semiconductor module according to claim 1, wherein
a gate wiring member electrically connected to the gate electrode of the first switching element is longer than a gate wiring member electrically connected to a gate electrode of the second switching element.

13. The semiconductor module according to claim 1, wherein
an auxiliary emitter wiring member electrically connected to the emitter electrode of the first switching element is longer than an auxiliary emitter wiring member electrically connected to an emitter electrode of the second switching element.

14. The semiconductor module according to claim 1, comprising:
a plurality of legs, each of which is constituted by an upper arm and a lower arm; and
a plurality of laminated substrates for arranging the plurality of legs, wherein
the plurality of legs are arranged on the plurality of laminated substrates, respectively.

15. The semiconductor module according to claim 1, comprising:
a plurality of legs, each of which is constituted by an upper arm and a lower arm; and
a laminated substrate for arranging the plurality of legs, wherein
the plurality of legs are arranged on the laminated substrate in common.

16. A semiconductor module comprising:
a reverse conducting first switching element which is provided on one of an upper arm and a lower arm;
a reverse conducting second switching element which is provided on another of the upper arm and the lower arm;
a first path member which is electrically connected to one of a gate electrode and an emitter electrode of the first switching element;
a second path member which is electrically connected to another of the gate electrode and the emitter electrode of the first switching element;
a gate external terminal which is electrically connected to the gate electrode of the first switching element via one of the first path member and the second path member;
an auxiliary emitter external terminal which is electrically connected to the emitter electrode of the first switching element via another of the first path member and the second path member; and
a positive electrode terminal and a negative electrode terminal which are provided on one predetermined side of the semiconductor module, wherein
the first path member is provided to be closer to the second switching element than the second path member,
current flowing through the first path member flows in antiparallel with a reverse recovery current of an arm provided with the second switching element, and
the positive electrode terminal and the negative electrode terminal are provided on a side orthogonal to a side on which the gate external terminal and the auxiliary emitter external terminal are provided.

17. The semiconductor module according to claim 16, wherein
the first path member is a gate wiring member electrically connected to the gate electrode of the first switching element, and
the second path member is an auxiliary emitter wiring member electrically connected to the emitter electrode of the first switching element.

18. The semiconductor module according to claim 16, wherein
the first path member is an auxiliary emitter wiring member electrically connected to the emitter electrode of the first switching element, and
the second path member is a gate wiring member electrically connected to the gate electrode of the first switching element.

19. The semiconductor module according to claim 16, wherein
the first path member and the second path member have a conductive circuit board, and
the circuit board of the first path member is provided between the circuit board of the second path member and the second switching element in a top view.

20. The semiconductor module according to claim 16, wherein
the first path member has a conductive circuit board,
the second path member has a conductive wire member, and
the circuit board of the first path member is provided to be closer to the second switching element than the wire member of the second path member.

21. The semiconductor module according to claim 16, wherein
the gate external terminal is provided to be closer to the second switching element than the auxiliary emitter external terminal.

22. The semiconductor module according to claim 16, wherein
the gate external terminal is provided to be farther from the second switching element than the auxiliary emitter external terminal.

23. The semiconductor module according to claim 21, comprising:
an output terminal which is provided on one predetermined side of the semiconductor module, wherein
the gate external terminal and the auxiliary emitter external terminal are provided on a side opposite to the side on which the output terminal is provided.

24. The semiconductor module according to claim 16, wherein
each of the first switching element and the second switching element is constituted by one chip.

25. The semiconductor module according to claim 24, wherein
the first switching element and the second switching element are any one of an RC-IGBT, an element in which a SiC-MOS and a SiC-SBD are integrated, or an element in which a body diode of the SiC-MOS is caused to function as a freewheeling diode.

26. The semiconductor module according to claim 16, wherein
a gate wiring member electrically connected to the gate electrode of the first switching element is longer than a gate wiring member electrically connected to a gate electrode of the second switching element.

27. The semiconductor module according to claim 16, wherein
an auxiliary emitter wiring member electrically connected to the emitter electrode of the first switching element is longer than an auxiliary emitter wiring member electrically connected to an emitter electrode of the second switching element.

28. The semiconductor module according to claim 16, comprising:
a plurality of legs, each of which is constituted by an upper arm and a lower arm; and
a plurality of laminated substrates for arranging the plurality of legs, wherein
the plurality of legs are arranged on the plurality of laminated substrates, respectively.

29. The semiconductor module according to claim 16, comprising:
a plurality of legs, each of which is constituted by an upper arm and a lower arm; and
a laminated substrate for arranging the plurality of legs, wherein
the plurality of legs are arranged on the laminated substrate in common.
